(19) United States
(12) Patent Application Publication
(10) Pub. No.: US 2025/0386510 A1
(43) Pub. Date: Dec. 18, 2025

(54) DIODE CONTAINING BIT LINE BIAS STRUCTURE AND METHODS FOR FORMING THE SAME

(71) Applicant: SANDISK TECHNOLOGIES LLC, ADDISON, TX (US)

(72) Inventors: Masashi ISHIDA, Yokkaichi (JP); Hiroshi NAKATSUJI, Yokkaichi (JP); Kosuke TANAKA, Yokkaichi (JP); Teppei SHINTAKU, Yokkaichi (JP); Kazutaka YOSHIZAWA, Yokkaichi (JP)

(21) Appl. No.: 18/811,152

(22) Filed: Aug. 21, 2024

Related U.S. Application Data
(60) Provisional application No. 63/661,275, filed on Jun. 18, 2024.

(51) Int. Cl. H10B 43/40; G11C 16/10; G11C 16/14; G11C 16/24; G11C 16/26; H01L 23/00; H01L 25/00; H01L 25/065; H01L 25/18; H10B 41/41; H10B 80/00

(52) U.S. Cl. CPC H10B 43/40; G11C 16/10; G11C 16/14; G11C 16/24; G11C 16/26; H01L 24/08; H01L 24/80; H01L 25/0657; H01L 25/18; H01L 25/50; H10B 41/41; H10B 80/00; H01L 2224/08145; H01L 2224/80006; H01L 2224/80895; H01L 2224/80896; H01L 2924/1431; H01L 2924/14511

(57) ABSTRACT

A semiconductor structure includes a three-dimensional memory array including a three-dimensional array of memory elements, word lines, and bit lines, and a bit line driver including an array of unit bit-line-bias structures. Each of the unit bit-line-bias structures includes a sense amplifier connection transistor and a bit line bias diode that are both electrically connected to a respective one of the bit lines.

### FIELD

The present disclosure relates generally to the field of semiconductor devices, and particularly to a three-dimensional memory device including diode containing bit line bias structures and methods for forming the same.

### BACKGROUND

Electrically biasing bit lines of a three-dimensional memory array is facilitated by a two transistor bit line driver that provides a switchable connection to a sense amplifier circuit or an erase bias voltage supply circuit.

### SUMMARY

According to an aspect of the present disclosure, a semiconductor structure includes a three-dimensional memory array including a three-dimensional array of memory elements, word lines, and bit lines, and a bit line driver including an array of unit bit-line-bias structures. Each of the unit bit-line-bias structures includes a sense amplifier connection transistor and a bit line bias diode that are both electrically connected to a respective one of the bit lines.

According to another aspect of the present disclosure, a method of forming a semiconductor structure comprises forming a three-dimensional memory array including a three-dimensional array of memory elements, word lines, and bit lines; forming a bit line driver comprising an array of unit bit-line-bias structures, wherein each of the unit bit-line-bias structures comprises a sense amplifier connection transistor and a bit line bias diode; and bonding the three-dimensional memory array to the bit line driver, such that both the sense amplifier connection transistor and the bit line bias diode are electrically connected to a respective one of the bit lines.

### BRIEF DESCRIPTION OF THE DRAWINGS

FIG. 1 is a schematic vertical cross-sectional view of an exemplary structure after formation of an alternating stack of insulating layers and sacrificial material layers over a carrier substrate according to an embodiment of the present disclosure.

FIG. 2 is a schematic vertical cross-sectional view of the exemplary structure after formation of stepped surfaces and a stepped dielectric material portion according to the embodiment of the present disclosure.

FIG. 3A is a schematic vertical cross-sectional view of the exemplary structure after formation of memory openings and support openings according to the embodiment of the present disclosure. FIG. 3B is a top-down view of the exemplary structure of FIG. 3A. The hinged vertical cross-sectional plane A-A′ is the cut plane of the vertical cross-sectional view of FIG. 3A.

FIG. 4 is a schematic vertical cross-sectional view of the exemplary structure after formation of sacrificial opening fill structures according to the embodiment of the present disclosure.

FIG. 5 is a vertical cross-sectional view of the exemplary structure after formation of support pillar structures according to the embodiment of the present disclosure.

FIG. 6 is a schematic vertical cross-sectional view of the exemplary structure after removal of sacrificial memory opening fill structures according to the embodiment of the present disclosure.

FIGS. 7A-7F are sequential vertical cross-sectional views of a memory opening during formation of a memory opening fill structure according to an embodiment of the present disclosure.

FIG. 8A is a schematic vertical cross-sectional view of the exemplary structure after formation of memory opening fill structures according to the embodiment of the present disclosure. FIG. 8B is a top-down view of the exemplary structure of FIG. 8A. The vertical plane A-A is the cut plane of the vertical cross-sectional view of FIG. 8A.

FIG. 9A is a vertical cross-sectional view of the exemplary structure after formation of lateral isolation trenches according to the embodiment of the present disclosure.

FIG. 9B is a top-down view of the exemplary structure of FIG. 9A. The vertical plane A-A is the cut plane of the vertical cross-sectional view of FIG. 9A.

FIG. 10 is a vertical cross-sectional view of the exemplary structure after formation of laterally-extending cavities according to the embodiment of the present disclosure.

FIG. 11 is a schematic vertical cross-sectional view of the exemplary structure after formation of electrically conductive layers according to the embodiment of the present disclosure.

FIG. 12A is a vertical cross-sectional view of the exemplary structure after formation of lateral isolation trench fill structures, layer contact via structures, and drain contact via structures according to an embodiment of the present disclosure. FIG. 12B is a top-down view of the exemplary structure of FIG. 12A. The vertical plane A-A is the cut plane of the vertical cross-sectional view of FIG. 12A.

FIG. 13 is a vertical cross-sectional view of the exemplary structure after formation of a memory die according to the embodiment of the present disclosure.

FIG. 14 is a vertical cross-sectional view of a logic die according to the embodiment of the present disclosure.

FIGS. 15A, 15B, 15C, and 15D are first, second, third, and fourth exemplary bit line drivers of the present disclosure, respectively.

FIGS. 16A and 16B are first and second exemplary circuit schematics of the bit line drivers of the present disclosure, respectively.

FIG. 17 is a vertical cross-sectional view of the exemplary structure after attaching the logic die to the memory die according to the embodiment of the present disclosure.

FIG. 18A is a vertical cross-sectional view of the exemplary structure after removal of the carrier substrate according to the embodiment of the present disclosure. FIG. 18B is a magnified view of region B of FIG. 18A.

FIG. 19A is a vertical cross-sectional view of the exemplary structure after formation of a source layer according to the embodiment of the present disclosure. FIG. 19B is a magnified view of region B of FIG. 19A.

FIG. 20 is a vertical cross-sectional view of the exemplary structure after formation of a backside dielectric layer and a source contact structure according to the embodiment of the present disclosure.

### DETAILED DESCRIPTION

As discussed above, the embodiments of the present disclosure are directed to a three-dimensional memory device including diode containing bit line bias structures and methods for forming the same, the various aspects of which are described below. Embodiments of the disclosure can be employed to form various semiconductor structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exists a physical contact between a surface of the element and a surface of the second element.

As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., the smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either upon formation as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flow is modulated by electric field applied by a gate electrode. A “source/drain region” refers to a doped semiconductor region that may function as a source region or a drain region. An “active region” refers to a source region of a field effect transistor or a drain region of a field effect transistor.

Conventional scaling of field effect transistor relies on reduction of the lateral extents of the active areas and the shallow trench isolation structures. However, reducing the lateral dimensions of the transistor active areas results in an increase in the backbias threshold voltage and reduces voltage transfer efficiency, and reducing the lateral dimensions of the shallow trench isolation structures increases the leakage current. Thus, reducing the area of transistors in the bit line driver circuit to electrically bias the bit lines is a challenge. Embodiments of the present disclosure are directed to a bit line driver employing an erase bias voltage diode instead of an erase bias voltage transistor. The diode typically has a smaller size (e.g., lateral foot print) than a field effect transistor. Use of the erase bias voltage diode allows for a reduction in the circuit width by eliminating the limitation posed by the backbias threshold voltage of the transistor. The bit line driver of the embodiments of the present disclosure provides effective bit line switching without increasing leakage current for the bit lines while reducing the circuit size.

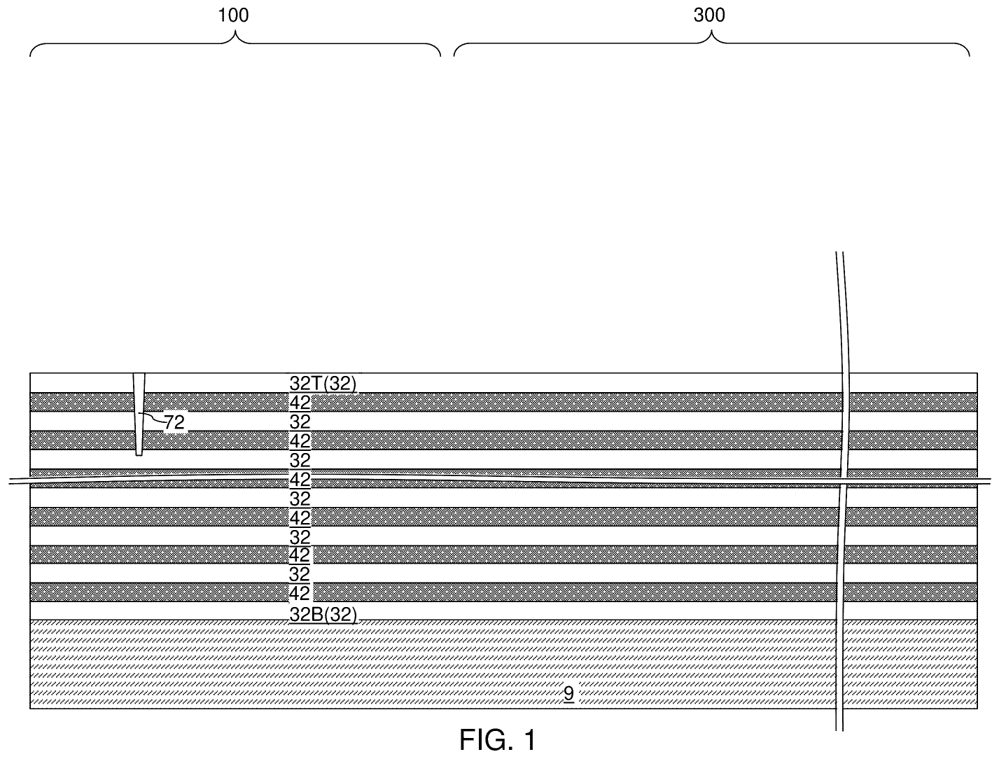

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selectively to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 laterally extending along a first horizontal direction hd1 may be formed through a subset of the topmost sacrificial material layers 42 which will be replaced with drain side select gate electrodes in a subsequent step.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

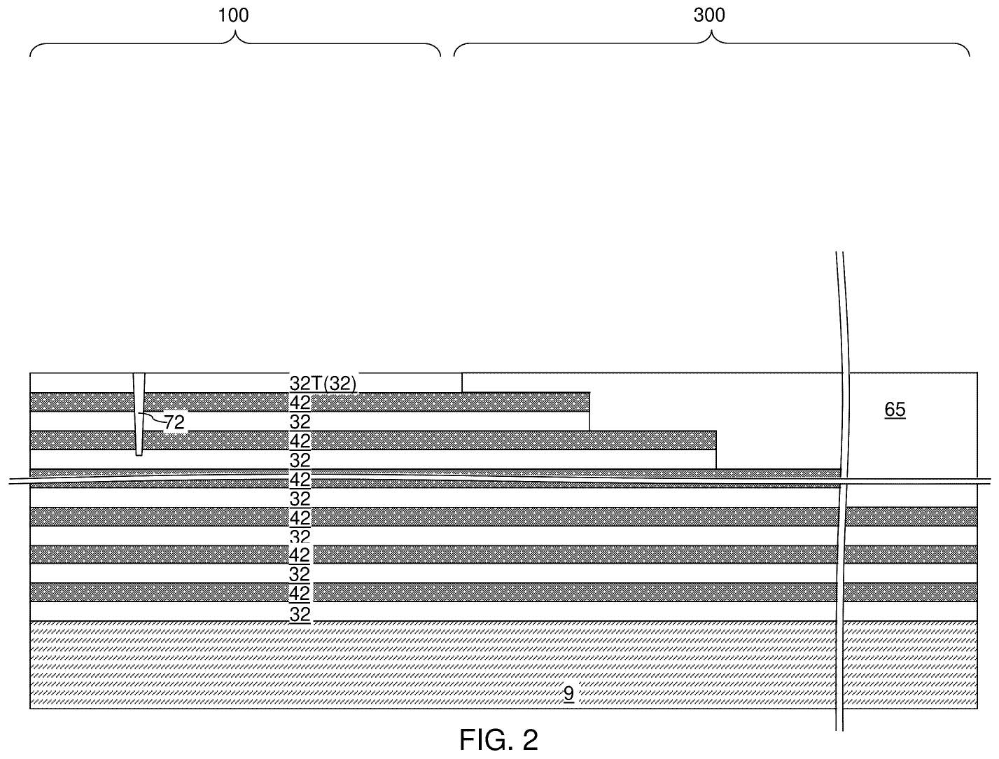

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from an edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including an alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

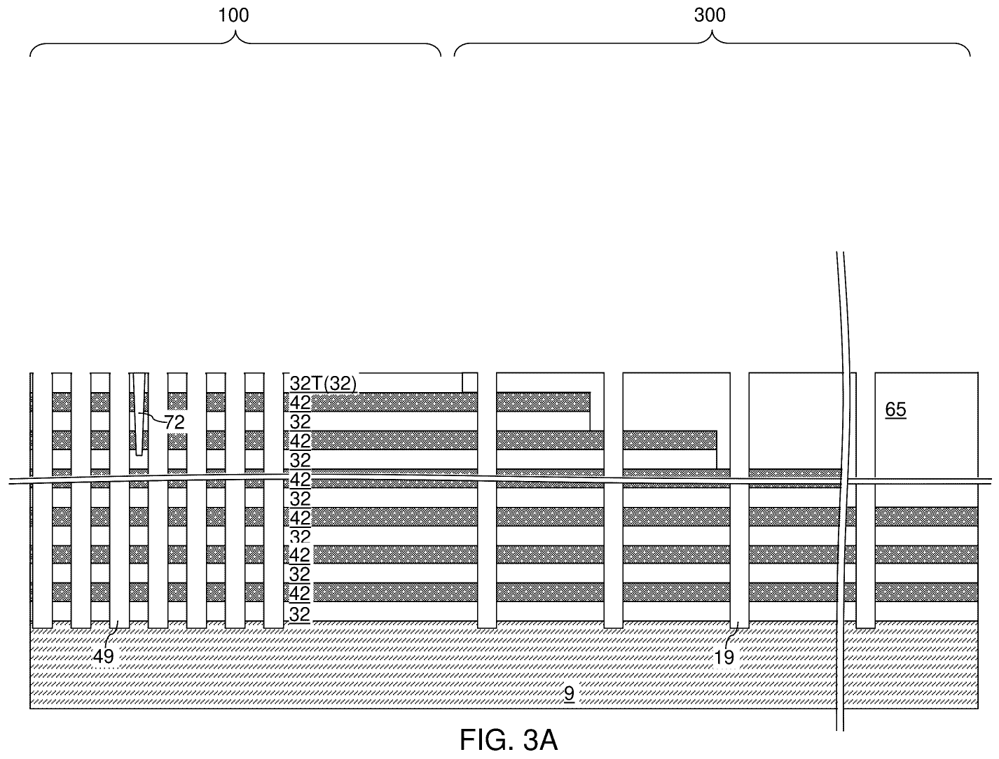

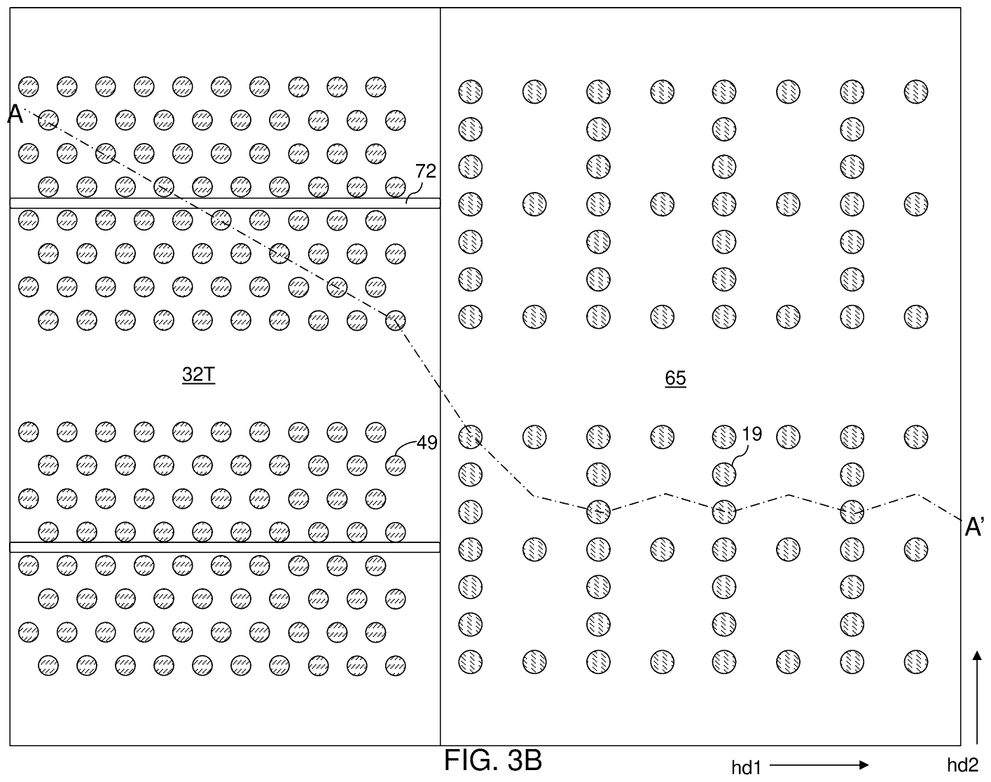

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater thicknesses may also be employed. The support openings 19 may have a diameter in a range from 60 nm to 400 nm, such as from 120 nm to 300 nm, although lesser and greater thicknesses may also be employed.

Each cluster of memory openings 49 may comprise a plurality of rows of memory openings 49 located in an area of a respective memory block. Each row of memory openings 49 may comprise a plurality of memory openings 49 that are arranged along the first horizontal direction (e.g., word line direction) hd1 with a uniform pitch. The rows of memory openings 49 may be laterally spaced from each other along the second horizontal direction (e.g., bit line direction) hd2, which may be perpendicular to the first horizontal direction hd2. In one embodiment, each cluster of memory openings 49 may be formed as a two-dimensional periodic array of memory openings 49.

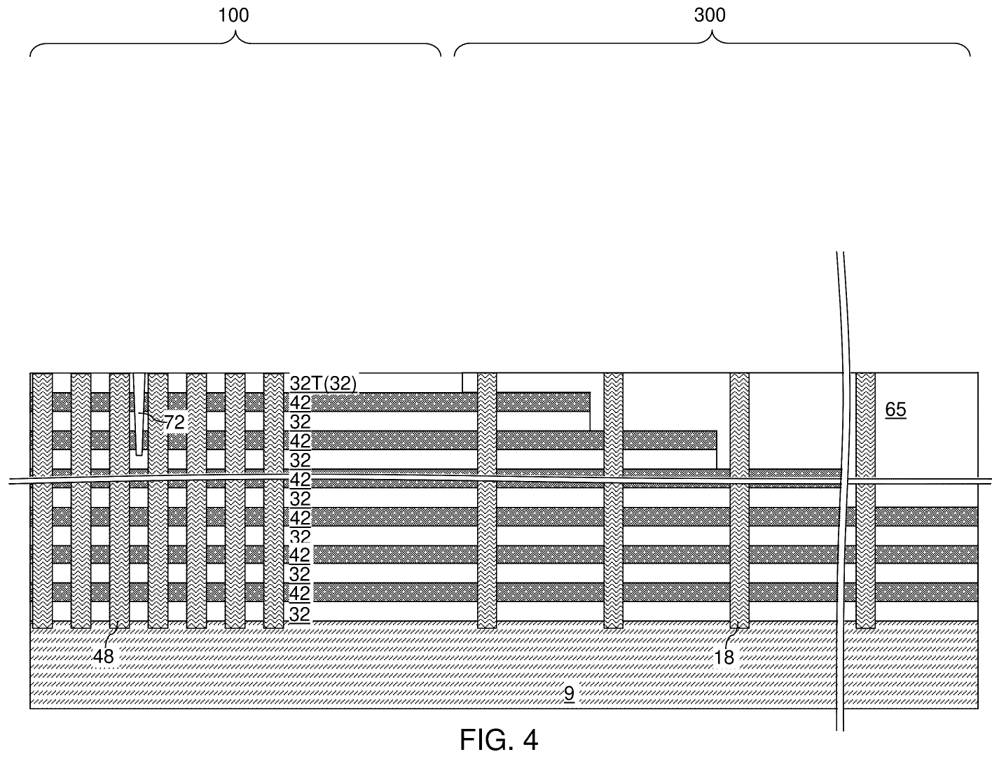

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material (such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

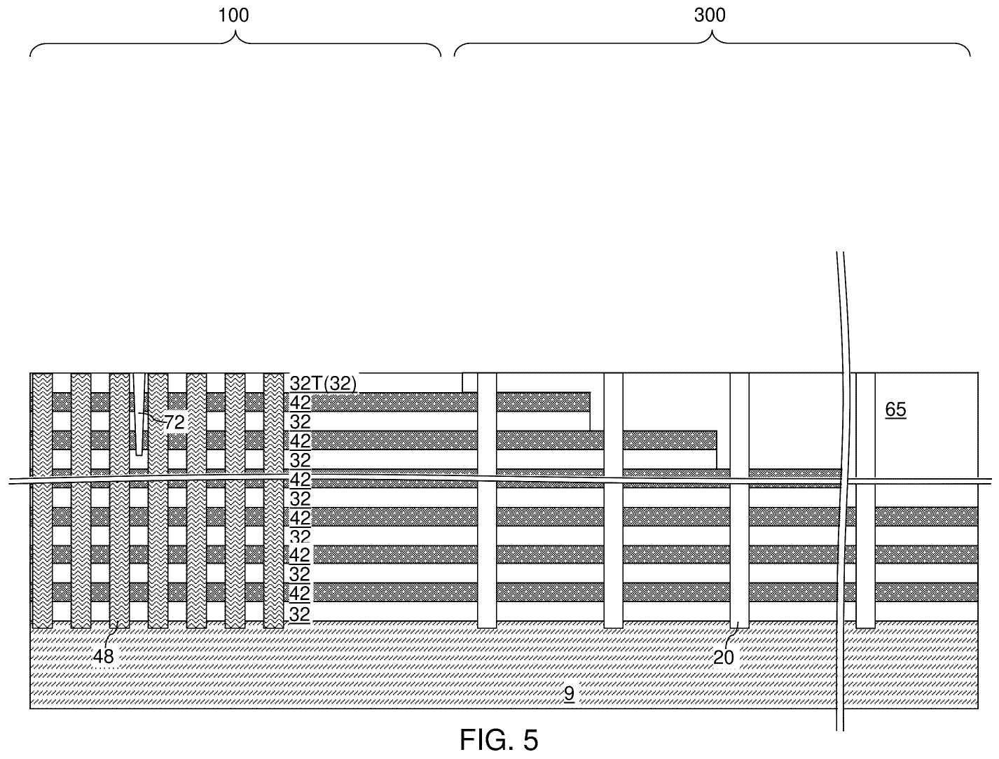

Referring to FIG. 5, a photoresist layer (not shown) can be applied over the exemplary structure, and can be lithographically patterned to cover the sacrificial memory opening fill structures 48 without covering the sacrificial support opening fill structures 18. The sacrificial support opening fill structures 18 are subsequently removed selectively to the materials of the insulating layers 32, the sacrificial material layers 42, and the carrier substrate 9. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

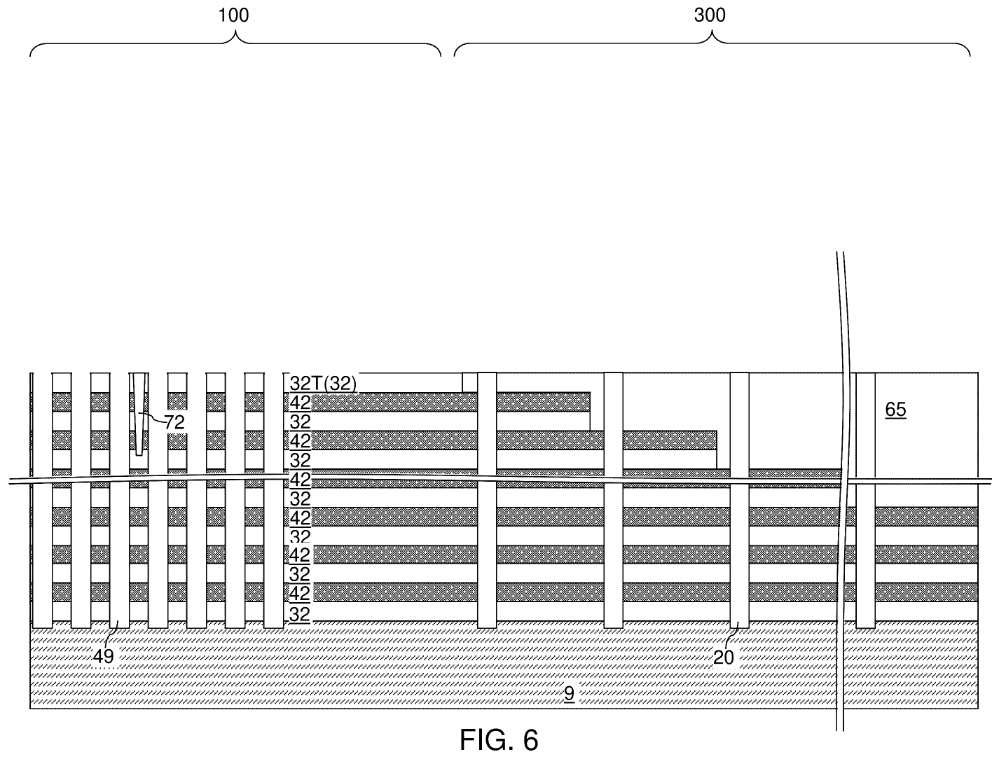

Referring to FIG. 6, sacrificial memory opening fill structures 48 are subsequently removed selectively to the materials of the insulating layers 32, the sacrificial material layers 42, and the carrier substrate 9. Voids are formed in the volumes of the memory openings 49 from which the sacrificial memory opening fill structures 48 are removed.

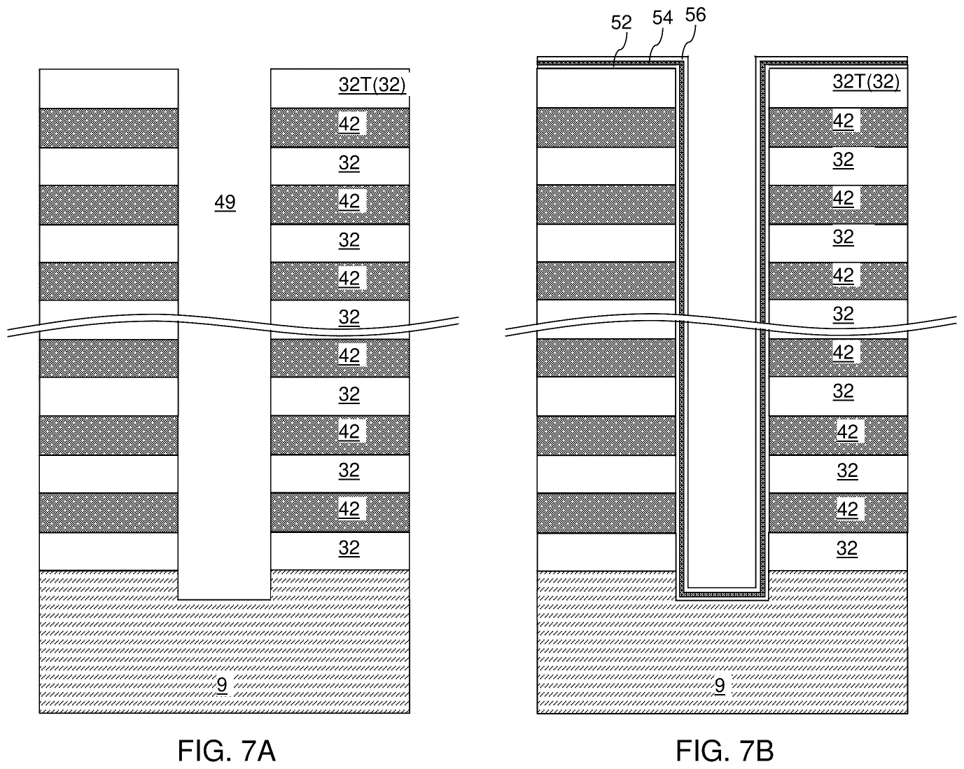

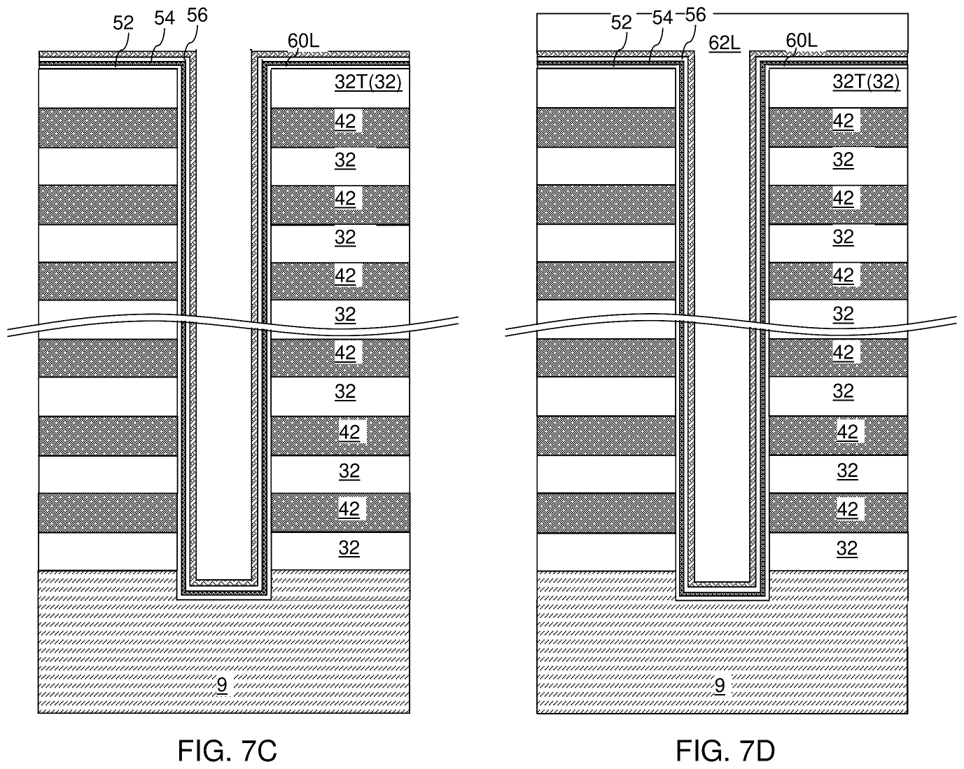

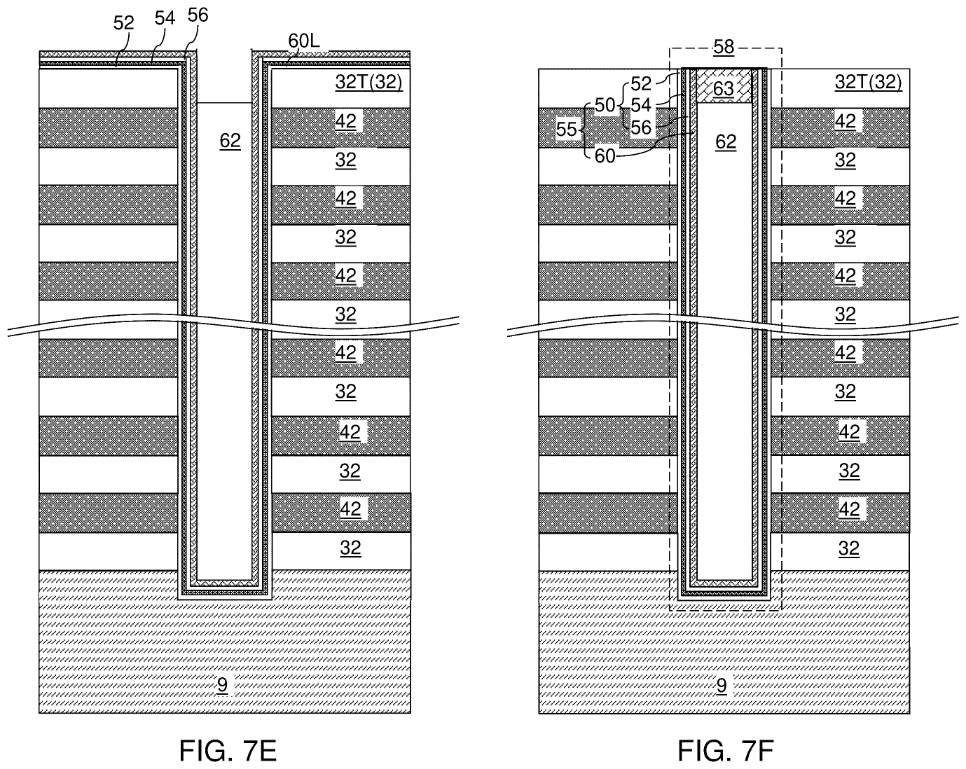

FIGS. 7A-7F are sequential vertical cross-sectional views of a memory opening 49 during formation of a memory opening fill structure 58 according to the embodiments of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In an alternative embodiment, the support pillar structures 20 may be formed in the support openings 19 at the same time as the memory opening fill structures 58 are formed in the memory openings 49. In this case, the support pillar structures 20 comprise dummy memory opening fill structures having the same materials as the memory opening fill structures 58.

An anneal process can be performed to activate electrical dopants in the drain region 63 and in the vertical semiconductor channel 60. In this case, any amorphous semiconductor material (e.g., amorphous silicon) in the vertical semiconductor channel 60 is converted into a polycrystalline semiconductor material (e.g., polysilicon).

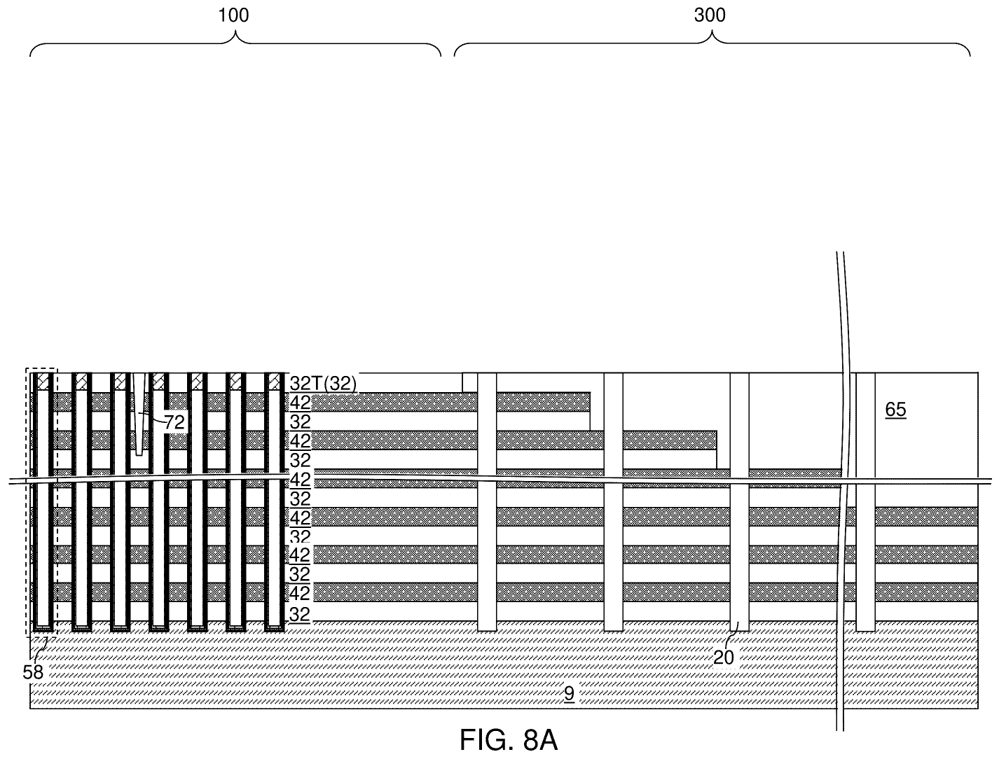

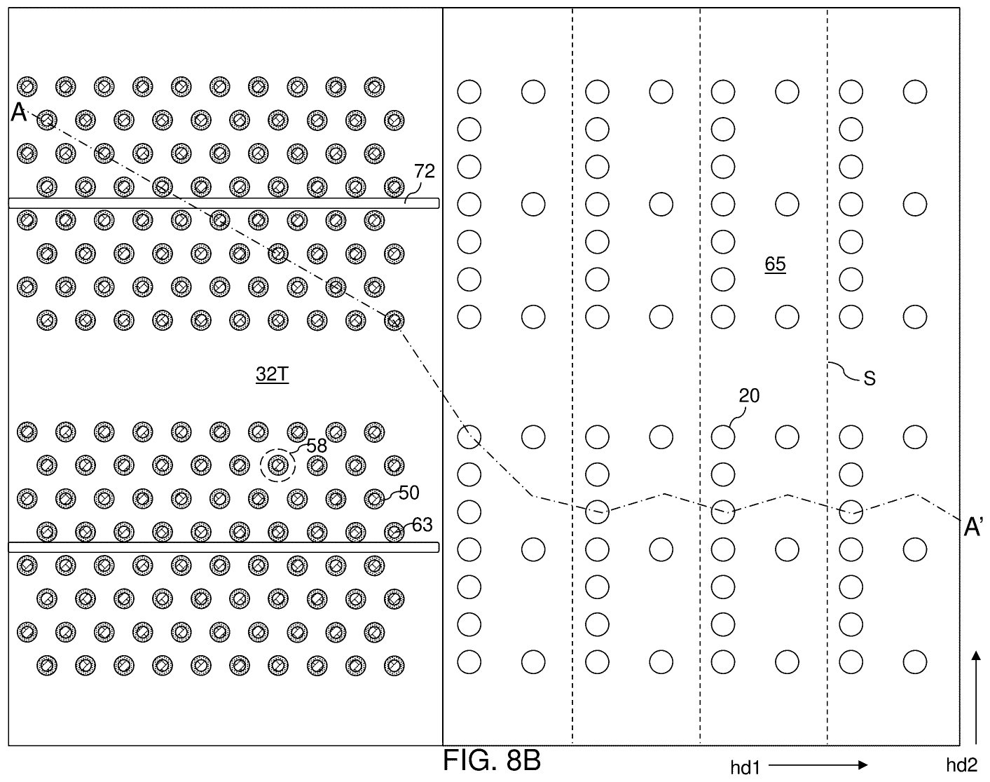

Referring to FIGS. 8A and 8B, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

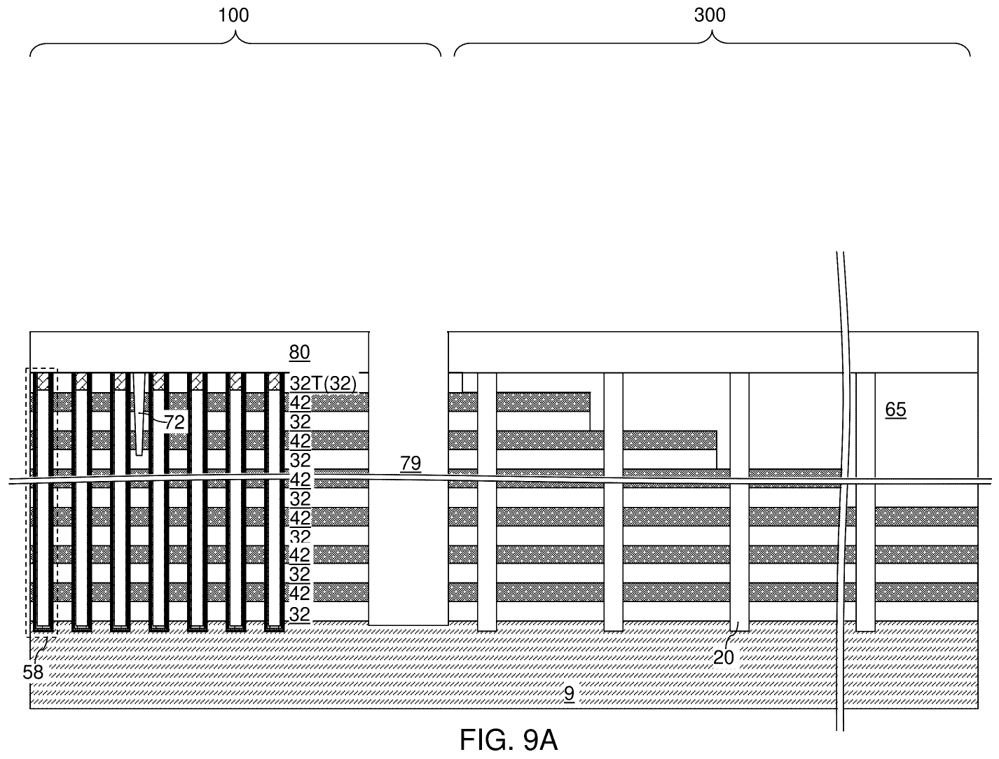

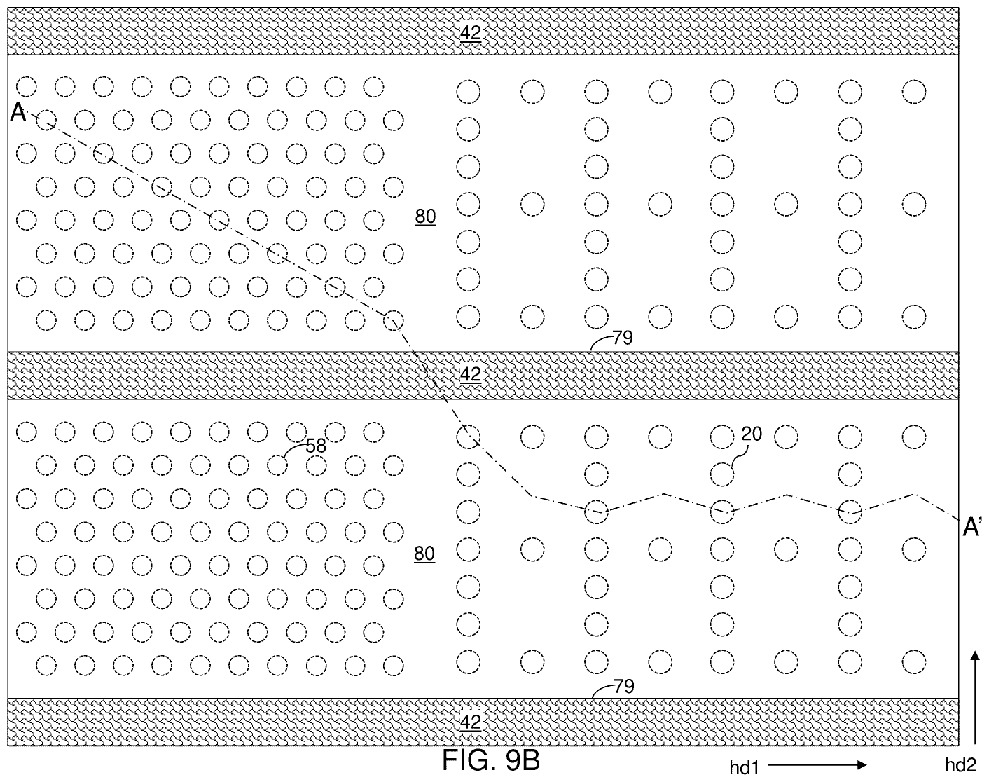

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

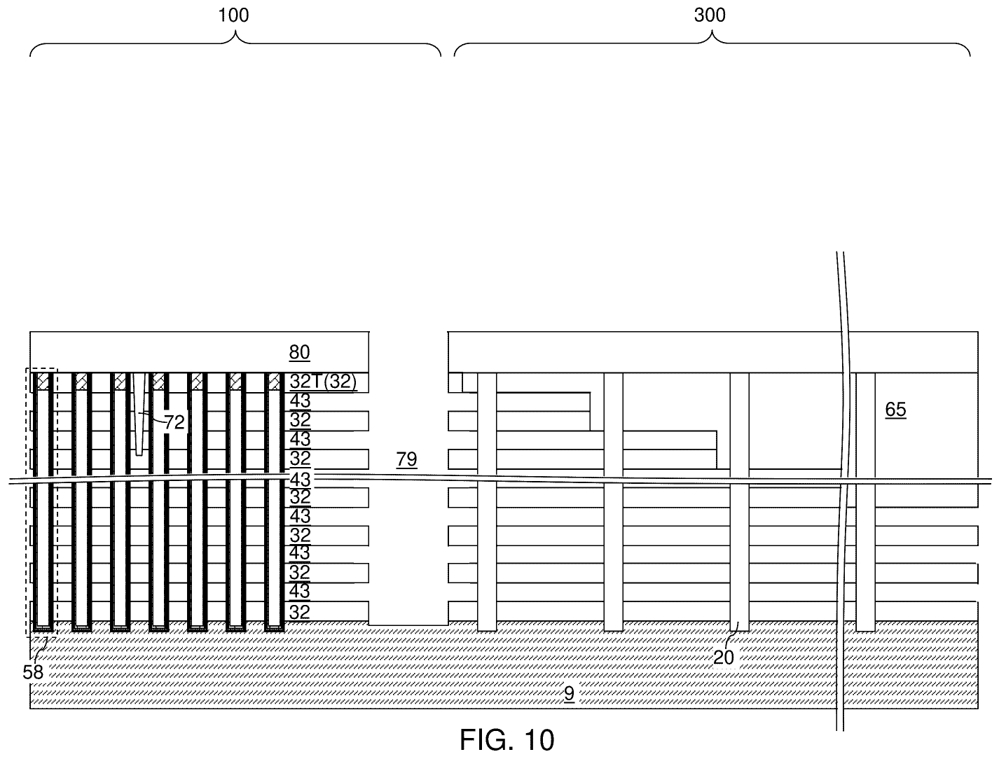

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structures 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

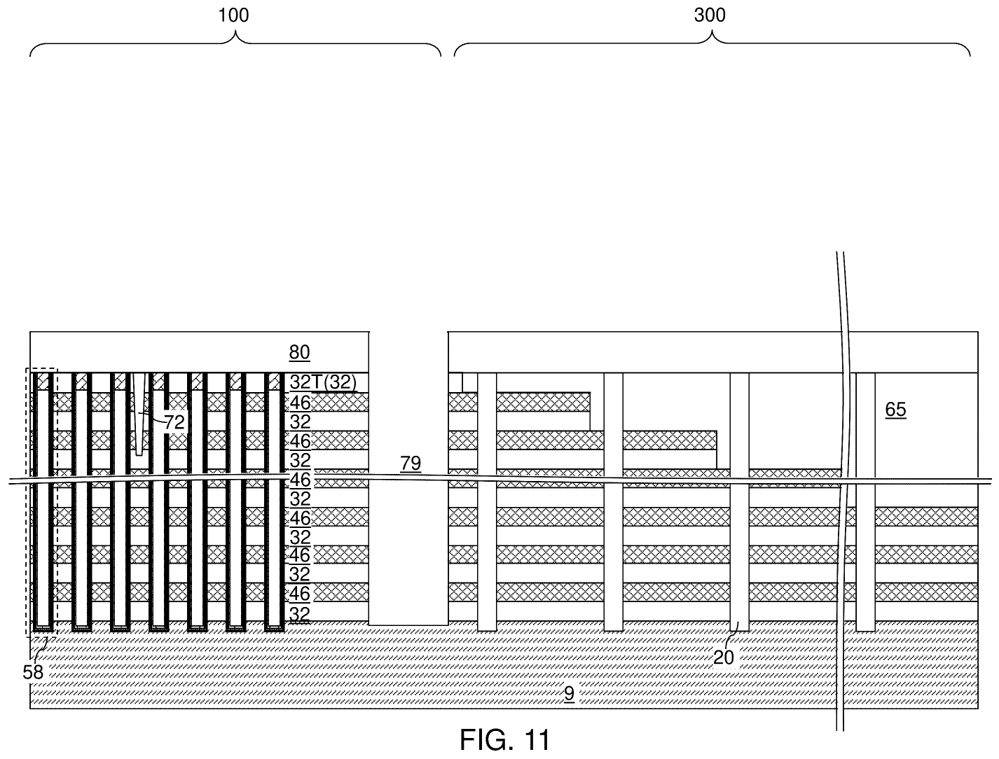

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

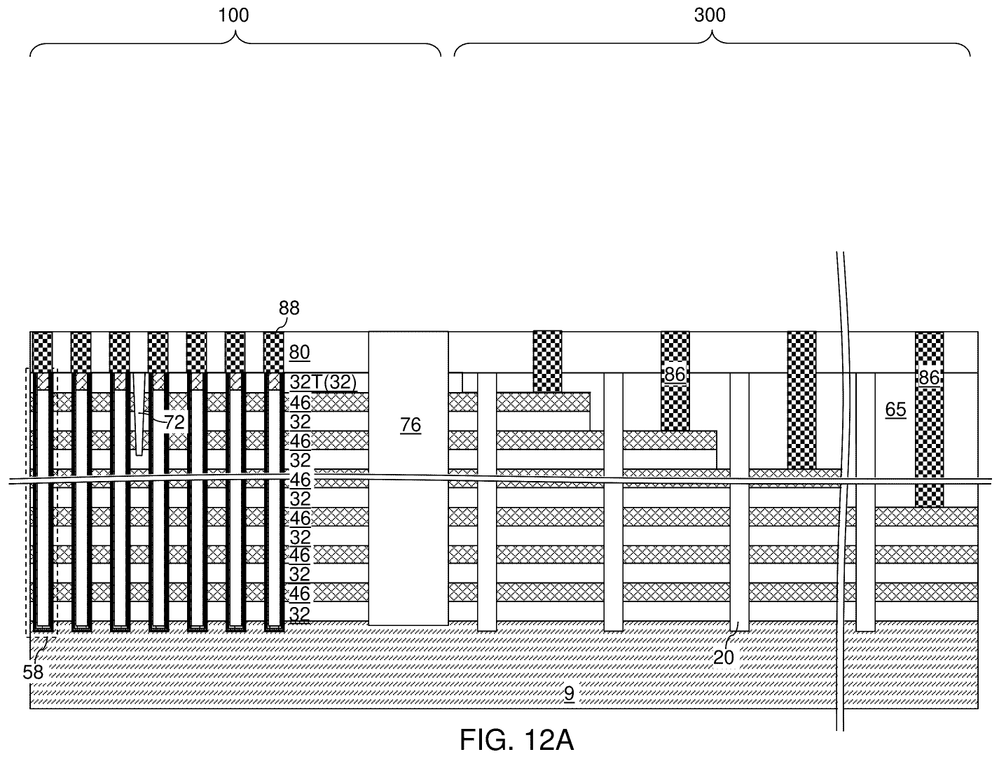

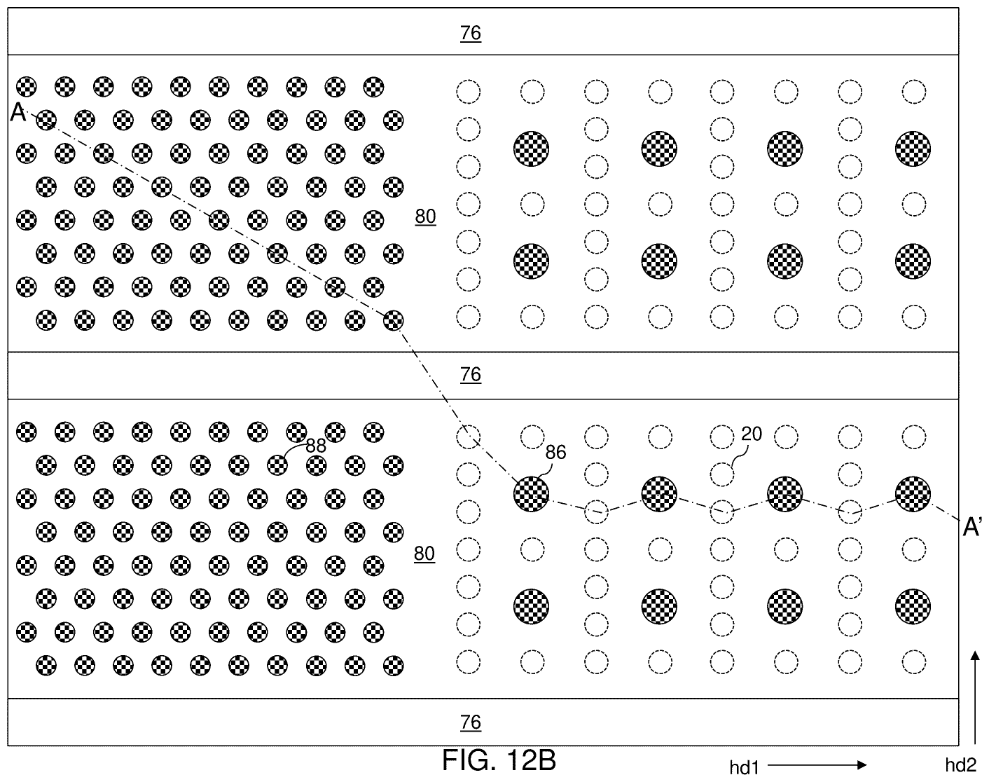

Referring to FIGS. 12A and 12B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

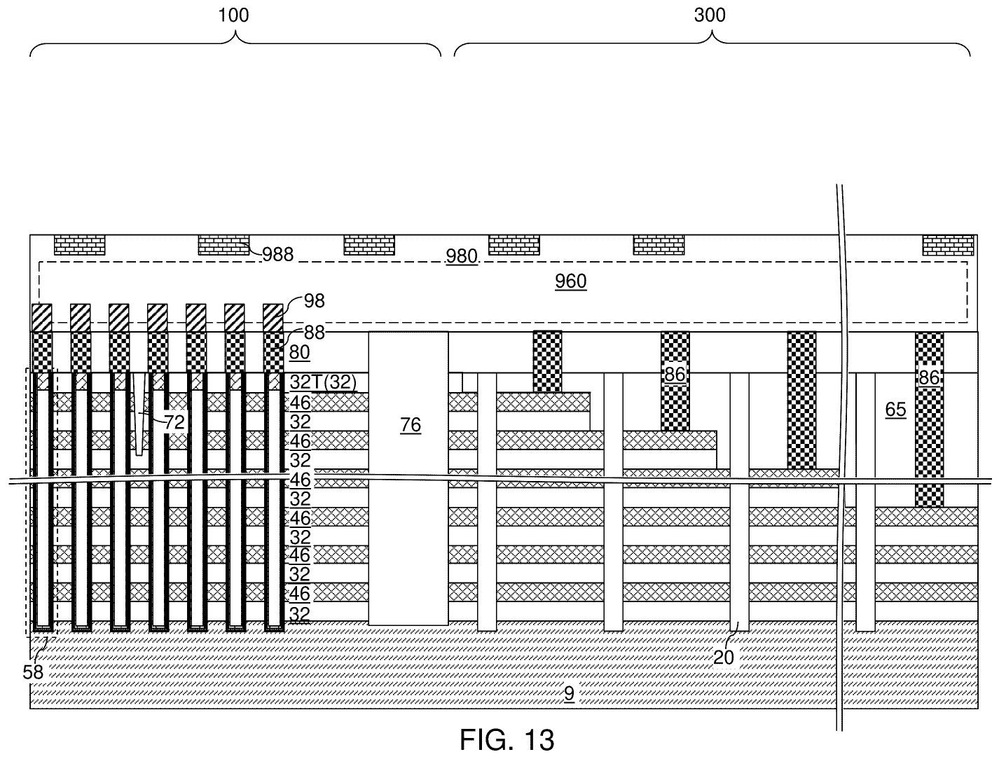

Referring to FIG. 13, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960.

The memory-side dielectric material layers 960 comprise a bit-line-level dielectric material layer (not expressly shown) embedding bit lines 98, which are a subset of the memory-side metal interconnect structures 980. In one embodiment, each bit line 98 may laterally extend along a horizontal direction (such as the second horizontal direction hd2) that is perpendicular to the lengthwise direction of the lateral isolation trench fill structures 76 (such as the first horizontal direction h1, e.g., word line direction), and may contact a respective column of drain contact via structures 88. Alternatively, each bit line 98 may contact a respective column of connection via structures (not illustrated) that contact top surfaces of a respective column of drain contact via structures 88. Thus, each bit line 98 can be electrically connected to, i.e., electrically shorted to, a respective column of drain regions 63 arranged along a horizontal direction that is perpendicular to the lengthwise direction of the lateral isolation trench fill structures 76.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

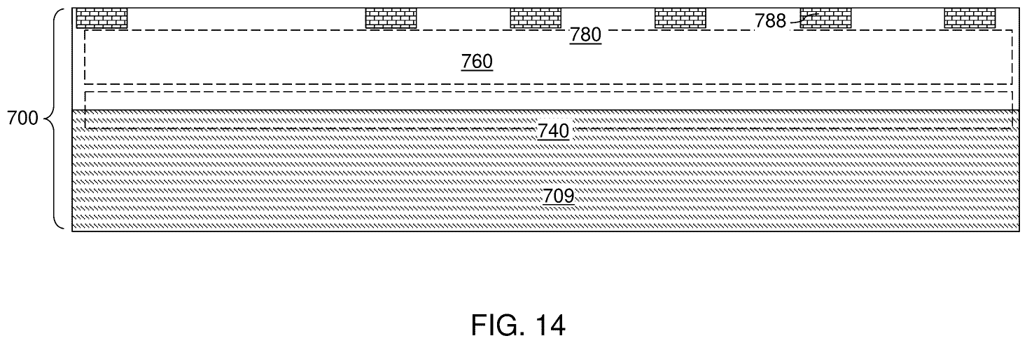

Referring to FIG. 14, a logic die 700 can be provided. The logic die 700 includes a semiconductor substrate 709, a peripheral circuit 740 located on the semiconductor substrate 709 and comprising logic-side semiconductor devices (such as field effect transistors and diodes), logic-side metal interconnect structures 780 embedded within logic-side dielectric material layers 760, and logic-side bonding pads 788.

The peripheral circuit 740 is configured to control operation of the memory array within the memory die 900. Specifically, the peripheral circuit 740 can be configured to drive various electrical components within the memory array including, but not limited to, the electrically conductive layers (e.g., word lines and select gate electrodes) 46, the bit lines 98 (and thus the drain regions 63), and at least one source contact structure to be subsequently formed. The peripheral circuit 740 can be configured to control operation of the vertical stack of memory elements (i.e., memory cells) in the memory array in the memory die 900. For example, the peripheral circuit 740 may comprise word line drivers configured to drive word lines, which are a subset of the electrically conductive layers 46 within the alternating stacks (32, 46). The peripheral circuit 740 may also comprise bit line drivers configured to drive the bit lines 98 in the memory die 900. The various aspects of the bit line drivers in the peripheral circuit 740 are described below. In one embodiment, as described with reference to the memory die 900, the bit lines 98 of a memory die 900 may be electrically connected to first ends (i.e., the ends that are connected to the drain regions 63) of a respective subset of the memory stack structures 55. The peripheral circuit 740 may also comprise source line drivers configured to drive source layers to be subsequently formed on the memory die 900 after removal of the carrier substrate 9. The peripheral circuit 740 may also comprise input/output control circuits configured to receive input data from, or to transmit output data to, at least one external bonding pad to be subsequently formed on the through-stack via structures 486 after removal of the carrier substrate 9. Generally, the peripheral circuit 740 may comprise any electronic circuit configured to manage data flow, handle read, erase and write operations, ensure data integrity through error correction, perform wear leveling to extend memory lifespan, and support communication protocols for interfacing with external devices and systems for the three-dimensional memory array in the memory die 900.

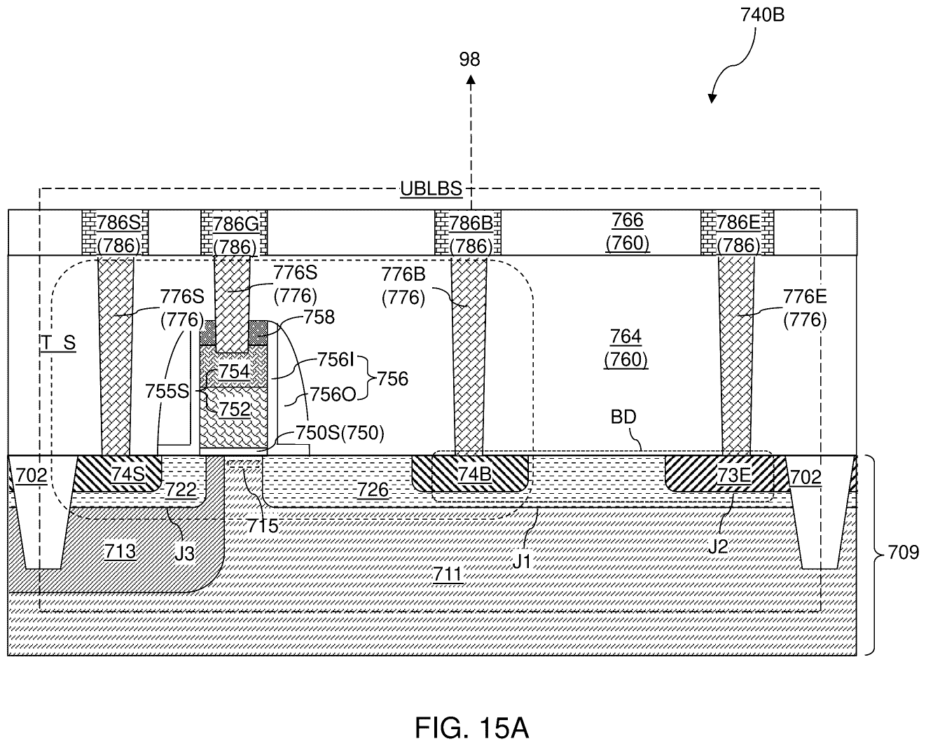

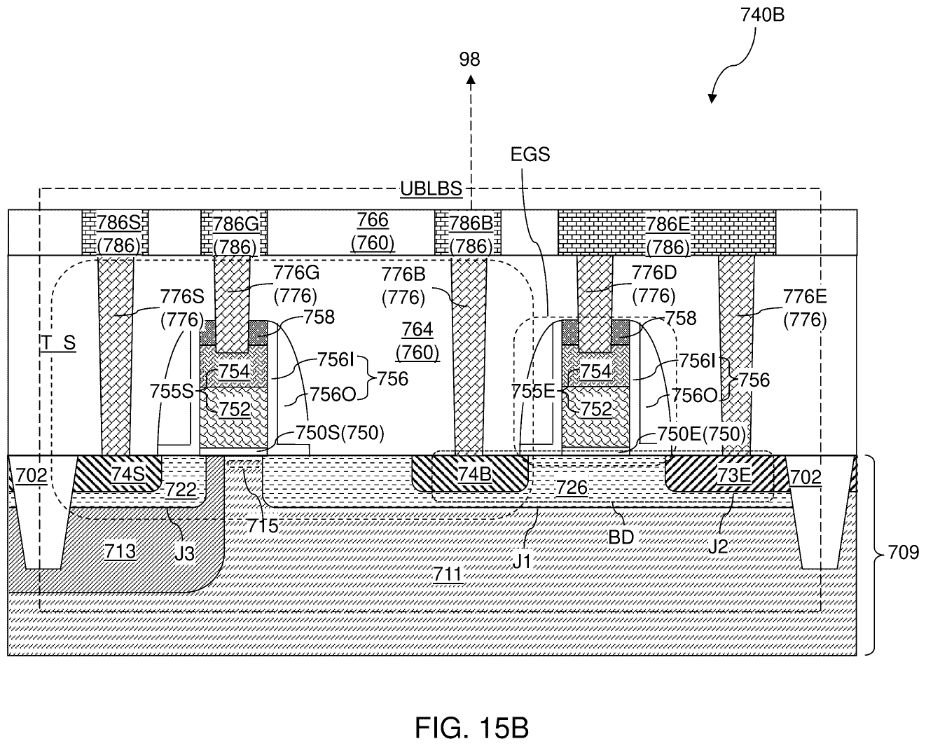

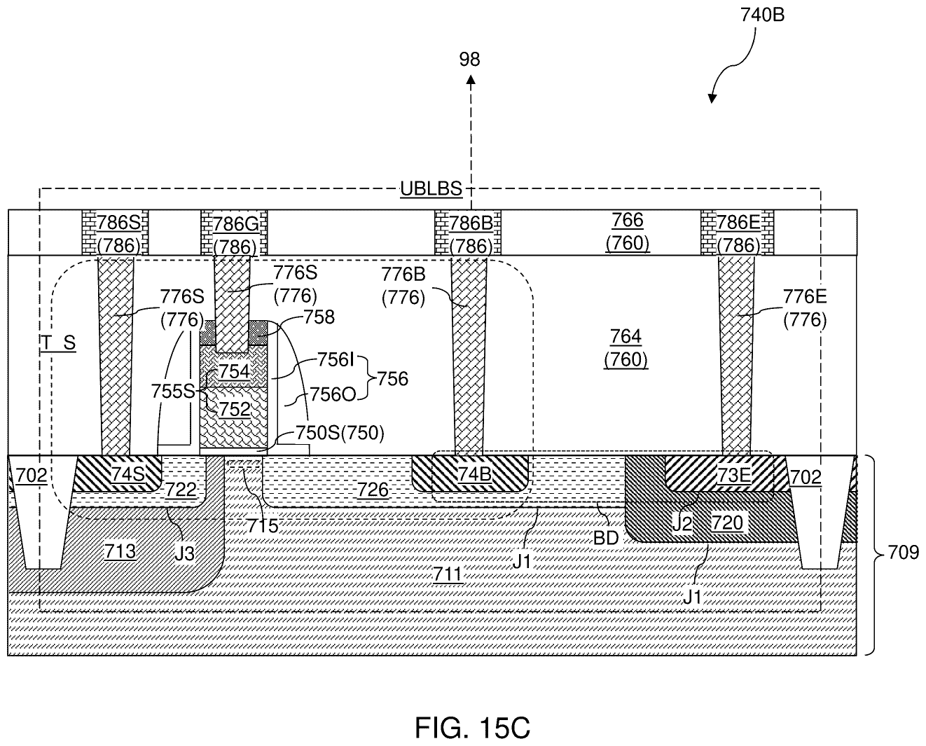

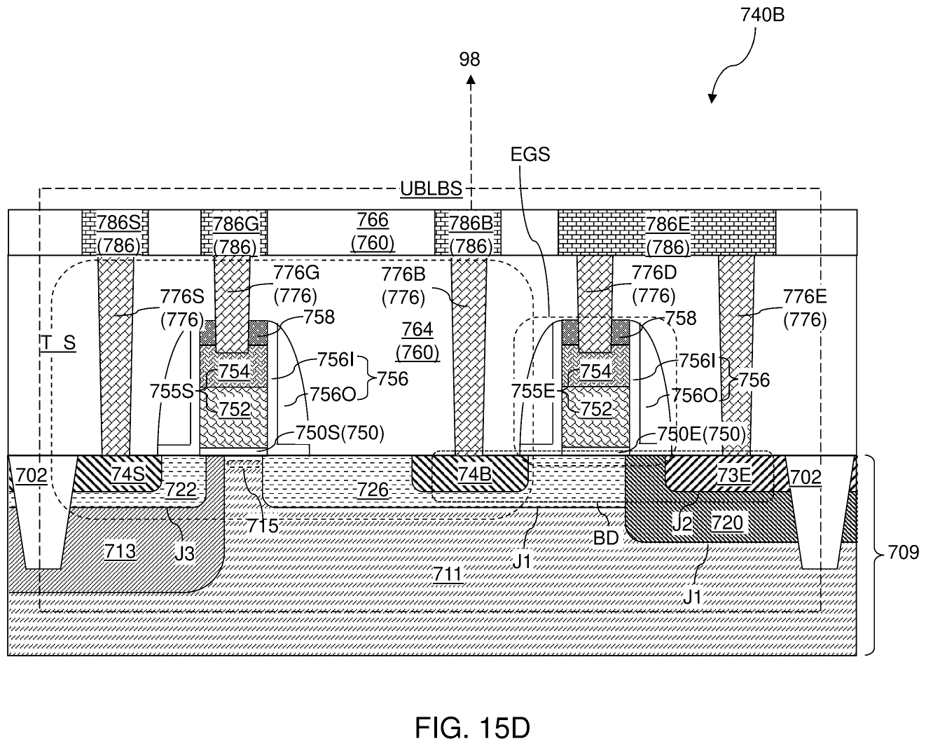

Referring collectively to FIGS. 15A, 15B, 15C, and 15D, the respective first, second, third, and fourth exemplary bit line drivers 740B that may be employed within the peripheral circuit 740 of the logic die 700 are illustrated. Generally, a bit line driver 740B comprises an array of unit bit-line-bias structures UBLBS. Each of FIGS. 15A, 15B, 15C, and 15D illustrates a unit bit-line-bias structure UBLBS that may be employed as a unit of repetition within the array of unit bit-line-bias structures UBLBS. Multiple instances of the unit bit-line-bias structure UBLBS may be repeated along at least one horizontal direction within each configuration of the bit line driver 740B. The total number of the unit bit-line-bias structures UBLBS may be the same as the total number of the bit lines 98 within the memory die 900.

In each configuration of the unit bit-line-bias structure UBLBS illustrated in FIGS. 15A, 15B, 15C, and 15D, the unit bit-line-bias structures UBLBS comprises a sense amplifier connection transistor (e.g., a bit line hook up transistor) T_S and a bit line bias diode BD that are both electrically connected to a respective bit line through a common doped region. The transistor is used during the programing and reading of the memory cells and the diode is activated during erasing of the memory cells.

The unit bit-line-bias structure UBLBS includes a p-doped substrate semiconductor material portion 711 located in a semiconductor substrate 709. The p-doped substrate semiconductor material portion 711 includes p-type dopants at a first p-type-dopant atomic concentration. In one embodiment, the p-doped substrate semiconductor material portion 711 may comprise an upper portion of the semiconductor substrate 709 as provided prior to implantation of any electrical dopants therein. For example, the semiconductor substrate 709 may comprise a commercially available p-doped single crystalline silicon wafer including p-type dopants at the first p-type-dopant atomic concentration, which may be in a range from 1×10¹⁴/cm³ to 1×10¹⁷/cm³, such as from 3×10¹⁴/cm³ to 3×10¹⁶/cm³, although lesser and greater atomic concentrations may also be employed. The p-doped substrate semiconductor material portion 711 comprises a portion of the semiconductor substrate 709 that is not implanted with any additional electrical dopants in processing steps that are employed to form the unit bit-line-bias structure UBLBS. As such, the entirety of the p-doped substrate semiconductor material portion 711 may comprise the p-type dopants at the first p-type dopant concentration. Prior to performing processing steps that introduce electrical dopants into the semiconductor substrate 709, the entirety of the semiconductor substrate 709 may include p-type dopants at the first p-type dopant concentration, and as such, constitute the p-doped substrate semiconductor material portion 711. Upon introduction of electrical dopants into various portions of the semiconductor substrate 709, the volume of the p-doped substrate semiconductor material portion 711 shrinks as the implanted portions of the semiconductor substrate 709 are converted to respective doped semiconductor material portions that do not belong to the p-doped substrate semiconductor material portion 711. In another embodiment, the p-doped substrate semiconductor material portion 711 may comprise a p-type doped well located in an upper portion of the semiconductor substrate 709. The p-type doped well may include p-type dopants at the first p-type-dopant atomic concentration, which may be in a range from 1×10¹⁴/cm³ to 1×10¹⁷/cm³, such as from 3×10¹⁴/cm³ to 3×10¹⁶/cm³, although lesser and greater atomic concentrations may also be employed.

A p-doped well 713 can be formed in a first surface portion of the semiconductor substrate 709 within each unit bit-line-bias structure UBLBS by implanting p-type dopants therein. The p-doped well 713 comprises p-type dopants at a second p-type dopant atomic concentration, which is a higher average atomic concentration than the first p-type-dopant atomic concentration. In one embodiment, the p-doped well 713 may comprise p-type dopants at an atomic concentration in a range from 1×10¹⁶/cm³ to 3×10¹⁸/cm³, such as from 3×10¹⁶/cm³ to 1×10¹⁸/cm³, although lesser and greater atomic concentrations may also be employed. The depth of the p-doped well 713 may be in a range from 200 nm to 600 nm, such as from 300 nm to 450 nm, although lesser and greater depths may also be employed.

Shallow trenches can be formed in an upper portion of the semiconductor substrate 709. The shallow trenches can be formed along the periphery of each unit bit-line-bias structure UBLBS so that semiconductor devices within each unit bit-line-bias structure UBLBS are electrically isolated from semiconductor devices within neighboring unit bit-line-bias structures UBLBS. If the unit bit-line-bias structures UBLBS are arranged as a one-dimensional array or a two-dimensional array, areas laterally surrounded by the shallow trenches may be arranged as the one-dimensional array or as the two-dimensional array. A dielectric fill material, such as silicon oxide, can be deposited in the shallow trenches, and excess portions of the dielectric fill material can be removed from above the horizontal plane including the top surface of the semiconductor substrate 709 by performing a planarization process. The planarization process may comprise a recess etch process and/or a chemical mechanical polishing process. The remaining portions of the dielectric fill material that filles the shallow trenches constitute shallow trench isolation structures 702. Generally, the entirety of the device area for a unit bit-line-bias structure UBLBS can be laterally surrounded by a respective portion of the shallow trench isolation structure 702. The vertical extent of the shallow trench isolation structures 702 may be in a range from 150 nm to 400 nm, such as from 200 nm to 300 nm, although lesser and greater vertical extents may also be employed.

In one embodiment, the bottom surfaces of the shallow trench isolation structures 702 may be formed above the horizontal plane including the bottom surface of the p-doped well 713. In other words, the depth of a bottom surface of the p-doped well 713 from a horizontal plane including a top surface of the semiconductor substrate 709 may be greater than the depth of the bottom surfaces of the shallow trench isolation structures 702 from the horizontal plane. Generally, an upper portion of the p-doped substrate semiconductor material portion 711 located within a unit bit-line-bias structure UBLBS can be laterally surrounded by a shallow trench isolation structure 702.

Subsequently, a sense amplifier connection transistor T_S can be formed. The sense amplifier connection transistor T_S comprises a channel region 715, which includes a surface region of the p-doped substrate semiconductor material portion 711. The sense amplifier connection transistor T_S comprises a first source/drain region (726, 74B) and a second source/drain region (722, 74S). The first source/drain region (726, 74B) is electrically connected to a respective bit line 98 in the memory die 900. The second source/drain region (722, 74S) is electrically connected to an input node of a respective sense amplifier that is provided as a component of the peripheral circuit 740. The sense amplifier is configured to measure the electrical current through the bit line 98, and to determine the memory state (e.g., the state of “0” or “1”) of a selected memory cell.

In one embodiment, the first source/drain region (726, 74B) comprises an optional first lightly n-doped extension region 726 and a first heavily n-doped semiconductor region 74B. The first heavily n-doped semiconductor region 74B is embedded within the first lightly n-doped extension region 726, and is electrically connected to a respective one of the bit lines 98. The second source/drain region (722, 74S) comprises an optional second lightly n-doped extension region 722 and a second heavily n-doped semiconductor region 74S. The second heavily n-doped semiconductor region 74S is embedded within the second lightly n-doped extension region 722, and is electrically connected to an input node of a sense amplifier. As used herein, a heavily doped semiconductor region refers to a region of a heavily doped semiconductor material, i.e., a semiconductor material that is doped with electrical dopants in a concentration in a range from 2×10¹⁸/cm³ to 5×10²¹/cm³. As used herein, a lightly doped semiconductor region refers to a doped semiconductor region having a doping at a dopant concentration that is less than that of the heavily doped semiconductor material.

The sense amplifier connection transistor T_S also comprises a sense amplifier transistor gate structure (750S, 755S, 758, 756) that overlies the channel region 715. The sense amplifier transistor gate structure (750S, 755S, 758, 756) may comprise a sense amplifier transistor gate dielectric 750S (which is a gate dielectric 750), a sense amplifier transistor gate electrode 755S, a gate cap dielectric 758, and a dielectric gate spacer 756. Generally, the sense amplifier transistor gate dielectric 750S may comprise any suitable gate dielectric material known in the art, such as silicon oxide or silicon oxynitride. The thickness of the sense amplifier transistor gate dielectric 750S may be in a range from 3 nm to 10 nm, although lesser and greater thicknesses may also be employed. In one embodiment, the sense amplifier transistor gate electrode 755S may comprise a vertical stack of a heavily doped semiconductor (e.g., polysilicon) gate electrode 752 and a metallic gate electrode 754. The gate cap dielectric 758 comprises a dielectric material, such as silicon nitride. The dielectric gate spacer 756 comprises at least one dielectric material, which may be any material that is suitable for forming a dielectric gate spacer known in the art. For example, the dielectric gate spacer 756 may comprise a combination of silicon oxide and silicon nitride. In one embodiment, the dielectric gate spacer 756 may comprise an inner dielectric gate spacer 7561 and an outer dielectric gate spacer 7560.

Generally, the first lightly n-doped extension region 726, the second lightly n-doped extension region 722, the first heavily n-doped semiconductor region 74B, and the second heavily n-doped semiconductor region 74S may be formed by performing ion implantation processes that implant n-type dopants into surface portions of the semiconductor substrate 709. In one embodiment, the first lightly n-doped extension region 726 and the second lightly n-doped extension region 722 may be simultaneously formed by performing a first source/drain ion implantation process before forming the dielectric gate spacer 756, and the first heavily n-doped semiconductor region 74B and the second heavily n-doped semiconductor region 74S may be simultaneously formed by performing a second source/drain ion implantation process after forming the dielectric gate spacer 756.

In one embodiment, the process parameters of the first source/drain ion implantation process may be selected such that the depth (i.e., the vertical extent) of each of the first lightly n-doped extension region 726 and the second lightly n-doped extension region 722 is less than the depth of the bottom surfaces of the shallow trench isolation structures 702. In an illustrative example, the depth of each of the first lightly n-doped extension region 726 and the second lightly n-doped extension region 722 may be in a range from 100 nm to 400 nm, such as from 150 nm to 300 nm, although lesser and greater depths may also be employed. The average atomic concentration of n-type dopants within the first lightly n-doped extension region 726 and the second lightly n-doped extension region 722 is herein referred to as a first n-type dopant atomic concentration, which may be in a range from 1×10¹⁶/cm³ to 1×10¹⁸/cm³, although lesser and greater atomic concentrations may also be employed.

In one embodiment, the process parameters of the second source/drain ion implantation process may be selected such that the depth (i.e., the vertical extent) of each of the first heavily n-doped semiconductor region 74B and the second heavily n-doped semiconductor region 74S is less than the depths of the first lightly n-doped extension region 726 and the second lightly n-doped extension region 722. In an illustrative example, the depth of each of the first heavily n-doped semiconductor region 74B and the second heavily n-doped semiconductor region 74S may be in a range from 30 nm to 200 nm, such as from 80 nm to 200 nm, although lesser and greater depths may also be employed. The average atomic concentration of n-type dopants within the first heavily n-doped semiconductor region 74B and the second heavily n-doped semiconductor region 74S is herein referred to as a second n-type dopant atomic concentration, which may be in a range from 2×10¹⁸/cm³ to 5×10²¹/cm³, although lesser and greater atomic concentrations may also be employed.

Generally, components of the sense amplifier transistor gate structure (750S, 755S, 758, 756) may be employed as a part of an ion implantation mask during the first source/drain ion implantation process and during the second source/drain ion implantation process. For example, the combination of the sense amplifier transistor gate dielectric 750S, the sense amplifier transistor gate electrode 755S, and the gate cap dielectric 758 may be employed as a part of an ion implantation mask during formation of the first lightly n-doped extension region 726 and the second lightly n-doped extension region 722, and the entirety of the sense amplifier transistor gate structure (750S, 755S, 758, 756) may be employed as a part of an ion implantation mask during formation of the first heavily n-doped semiconductor region 74B and the second heavily n-doped semiconductor region 74S. Edges of the first lightly n-doped extension region 726 and the second lightly n-doped extension region 722 may be self-aligned to sidewalls of the vertical stack of the sense amplifier transistor gate dielectric 750S, the sense amplifier transistor gate electrode 755S, and the gate cap dielectric 758. A proximal edge of the second heavily n-doped semiconductor region 74S can be self-aligned to an outer sidewall of the dielectric gate spacer 756 that laterally surrounds the vertical stack of the sense amplifier transistor gate dielectric 750S, the sense amplifier transistor gate electrode 755S, and the gate cap dielectric 758.

In one embodiment, a patterned photoresist layer (not shown) can be employed as another part of an ion implantation mask during the second source/drain ion implantation process. Thus, the combination of the sense amplifier transistor gate structure (750S, 755S, 758, 756) and the patterned photoresist layer can be employed as an ion implantation mask during the second source/drain ion implantation process that forms the first heavily n-doped semiconductor region 74B and the second heavily n-doped semiconductor region 74S. According to an aspect of the present disclosure, the patterned photoresist layer does not cover the area of the second lightly n-doped extension region 722, but covers a peripheral area of the first lightly n-doped extension region 726 such that an opening in the patterned photoresist layer overlies a center portion of the first lightly n-doped extension region 726. In this case, the first heavily n-doped semiconductor region 74B can be laterally spaced from the sense amplifier transistor gate structure (750S, 755S, 758, 756). This configuration reduces the leakage current through the channel region 715 while the sense amplifier connection transistor T_S is turned off.

Generally, top edges of the first lightly n-doped extension region 726, the second lightly n-doped extension region 722, and the second heavily n-doped semiconductor region 74S may be self aligned to sidewalls of components of the sense amplifier transistor gate structure (750S, 755S, 758, 756) with a respective lateral offset, which is determined by the lateral straggle of implanted n-type dopants that are implanted during formation of the first lightly n-doped extension region 726, the second lightly n-doped extension region 722, the first heavily n-doped semiconductor region 74B, and the second heavily n-doped semiconductor region 74S. A proximal top edge of the first heavily n-doped semiconductor region 74B can be laterally offset from the sense amplifier transistor gate structure (750S, 755S, 758, 756) by a lateral offset distance, which is determined by a pattern in a patterned photoresist layer that is employed as a part of an ion implantation mask during the second source/drain ion implantation process.

In some embodiments illustrated in FIGS. 15B and 15D, an erase-side gate structure EGS may be formed in a bit line bias region that is more distal from the sense amplifier transistor gate structure (750S, 755S, 758, 756) than a proximal top edge of the first heavily n-doped semiconductor region 74B is from the sense amplifier transistor gate structure (750S, 755S, 758, 756). The erase-side gate structure EGS may be formed concurrently with formation of the sense amplifier transistor gate structure (750S, 755S, 758, 756). The erase-side gate structure EGS is a dummy gate structure that overlies the bit line bias diode BD and is electrically connected to one of the nodes of the bit line bias diode BD.

The erase-side gate structure EGS may comprise an erase gate dielectric 750E (which is a gate dielectric 750), an erase gate electrode 755E, a gate cap dielectric 758, and a dielectric gate spacer 756. The erase gate dielectric 750E may have the same thickness and/or the same material composition as the sense amplifier transistor gate dielectric 750S, and/or may have a different thickness and/or a different material composition than the sense amplifier transistor gate dielectric. In one embodiment, the erase gate electrode 755E may comprise a vertical stack of a semiconductor gate electrode 752 and a metallic gate electrode 754. The gate cap dielectric 758 of the erase-side gate structure EGS comprises a dielectric material such as silicon nitride. The dielectric gate spacer 756 of the erase-side gate structure EGS comprises at least one dielectric material, which may be any material that is suitable for forming a dielectric gate spacer known in the art. For example, the dielectric gate spacer 756 of the erase-side gate structure EGS may comprise a combination of silicon oxide and silicon nitride. In one embodiment, the dielectric gate spacer 756 of the erase-side gate structure EGS may comprise an inner dielectric gate spacer 7561 and an outer dielectric gate spacer 7560.

In one embodiment, the vertical stack of the semiconductor gate electrode 752, the metallic gate electrode 754, and the gate cap dielectric 758 of the erase-side gate structure EGS and the vertical stack of the semiconductor gate electrode 752, the metallic gate electrode 754, and the gate cap dielectric 758 of the sense amplifier transistor gate structure (750S, 755S, 758, 756) may be formed by deposition and patterning of a layer stack including a gate dielectric layer, a doped semiconductor material layer, a metallic gate electrode material layer, and a gate cap dielectric material layer. The dielectric gate spacers 756 around the erase-side gate structure EGS or the sense amplifier transistor gate structure (750S, 755S, 758, 756) may be formed by deposition and anisotropic etching of at least one dielectric gate spacer material layer.

If the erase-side gate structure EGS is formed, at least the portion of the first lightly n-doped extension region 726 that underlies the erase-side gate structure EGS may be formed prior to formation of the erase-side gate structure EGS by performing an ion implantation process, which may be performed in addition to the first source/drain ion implantation process or in lieu of the first source/drain ion implantation process.

In one embodiment, the erase-side gate structure EGS is formed and the first lightly n-doped extension region 726 is formed by performing two ion implantation steps, which include an ion implantation step that implants n-type dopants within areas underlying the erase-side gate structure EGS that is to be subsequently formed and the first source/drain ion implantation process. In this case, the combination of two semiconductor regions implanted with n-type dopants constitutes the first lightly n-doped extension region 726, and an edge of the first lightly n-doped extension region 726 may be aligned to a sidewall of a vertical stack of a sense amplifier transistor gate dielectric 750S, a sense amplifier transistor gate electrode 755S, and a gate cap dielectric 758. In addition, the first lightly n-doped extension region 726 may have a lateral modulation in the atomic concentration of n-type electrical dopants.

In one embodiment, the first lightly n-doped extension region 726 is formed by performing the first source/drain ion implantation process prior to formation of the vertical stack of a sense amplifier transistor gate dielectric 750S, a sense amplifier transistor gate electrode 755S, and a gate cap dielectric 758 and prior to formation of the vertical stack of an erase gate dielectric 750E, an erase gate electrode 755E, and a gate cap dielectric 758. In this case, an edge of the first lightly n-doped extension region 726 that underlies the vertical stack of the sense amplifier transistor gate dielectric 750S, the sense amplifier transistor gate electrode 755S, and the gate cap dielectric 758 is not formed by a self-aligned ion implantation process, and thus, a random variation of the overlap may occur between the first lightly n-doped extension region 726 and the vertical stack of the sense amplifier transistor gate dielectric 750S, the sense amplifier transistor gate electrode 755S.

Generally, an edge of the second heavily n-doped semiconductor region 74S may be self-aligned to an outer sidewall of a dielectric gate spacer 756 within the sense amplifier transistor gate structure (750S, 755S, 758, 756). If an erase-side gate structure EGS is formed (for example, in embodiments illustrated in FIGS. 15B and 15D), an edge of the first heavily n-doped semiconductor region 74B may be self-aligned to an outer sidewall of a dielectric gate spacer 756 within the erase-side gate structure EGS.

According to an aspect of the present disclosure, a heavily p-doped semiconductor region 73E is formed in a peripheral region (e.g., the bit line bias diode BD region) of the unit bit-line-bias structure UBLBS that is distal from the second heavily n-doped semiconductor region 74S. A masked ion implantation process may be performed to implant p-type dopants in the peripheral region of the unit bit-line-bias structure UBLBS. The masked ion implantation process employs a patterned photoresist layer including an opening over the peripheral region of the unit bit-line-bias structure UBLBS that is distal from the second heavily n-doped semiconductor region 74S. If the erase-side gate structure EGS is omitted, the location of a sidewall of an opening in the patterned photoresist layer defines the location of a sidewall of the heavily p-doped semiconductor region 73E that faces the first heavily n-doped semiconductor region 74B. If the erase-side gate structure EGS is present, the masked ion implantation process may be performed after formation of the erase-side gate structure EGS, and the erase-side gate structure EGS may also be employed as a masking structure during the masked ion implantation process. In this case, the sidewall of the heavily p-doped semiconductor region 73E that faces the first heavily n-doped semiconductor region 74B may be self-aligned to an outer sidewall of the dielectric gate spacer 756 of the erase-side gate structure EGS. Generally, the heavily p-doped semiconductor region 73E is laterally spaced from the sense amplifier transistor gate structure (750S, 755S, 758, 756) by a greater lateral spacing than the first heavily n-doped semiconductor region 74B is from the sense amplifier transistor gate structure (750S, 755S, 758, 756).

In one embodiment, the process parameters of the ion implantation process that forms the heavily p-doped semiconductor region 73E may be selected such that the depth (i.e., the vertical extent) of the heavily p-doped semiconductor region 73E is less than the depths of the first lightly n-doped extension region 726 and the second lightly n-doped extension region 722. In an illustrative example, the depth of the heavily p-doped semiconductor region 73E may be in a range from 30 nm to 200 nm, such as from 80 nm to 200 nm, although lesser and greater depths may also be employed. The average atomic concentration of p-type dopants within the heavily p-doped semiconductor region 73E is herein referred to as a third p-type dopant atomic concentration, which may be in a range from 2×10¹⁸/cm³ to 5×10²¹/cm³, although lesser and greater atomic concentrations may also be employed.

The heavily p-doped semiconductor region 73E is electrically connected to an output node of an erase bias voltage supply circuit. The heavily p-doped semiconductor region 73E is laterally spaced from the first heavily n-doped semiconductor region 74B at least by a portion of the first lightly n-doped extension region 726. A second p-n junction J2 is formed at a sidewall and a bottom surface of the heavily p-doped semiconductor region 73E. As discussed above, a first p-n junction J1 is present between the first source/drain region (726, 74B) and the p-doped substrate semiconductor material portion 711. A third p-n junction J3 can be present at the sidewall and the bottom surface of the second source/drain region (722, 74S), which may be the sidewall and the bottom surface of the second lightly n-doped extension region 722.

In one embodiment, no additional doped well may be formed between the heavily p-doped semiconductor region 73E and the first heavily n-doped semiconductor region 74B, as illustrated in FIGS. 15A and 15B. In this case, the sidewall and the bottom surface of the heavily p-doped semiconductor region 73E are in contact with the first lightly n-doped extension region 726. In one embodiment, the entirety of the bottom surface of the heavily p-doped semiconductor region 73E is in contact with the first lightly n-doped extension region 726. In one embodiment, the entirety of a first sidewall of the heavily p-doped semiconductor region 73E is in contact with the first lightly n-doped extension region 726. In one embodiment, the entirety of a second sidewall of the heavily p-doped semiconductor region 73E is in contact with a shallow trench isolation structure 702. In one embodiment, the horizontally-extending portion of the second p-n junction J2 is vertically spaced from the horizontally-extending portion of the first p-n junction J1 by a uniform vertical spacing, which equals the difference between the depth of the bottom surface of the first lightly n-doped extension region 726 and the depth of the bottom surface of the heavily p-doped semiconductor region 73E. For example, the uniform vertical spacing may be in a range from 30 nm to 200 nm, such as from 60 nm to 100 nm, although lesser and greater dimensions may also be employed.

In other embodiments illustrated in FIGS. 15C and 15D, an additional n-doped well 720 may be formed around the region of the heavily p-doped semiconductor region 73E prior to or after formation of the heavily p-doped semiconductor region 73E. The n-doped well 720 is located between the heavily p-doped semiconductor region 73E and the first heavily n-doped semiconductor region 74B.

In one embodiment, the n-doped well 720 can be formed by performing a masked ion implantation process in which n-type dopants are implanted into an unmasked surface portion of the semiconductor substrate 709. If an erase-side gate structure EGS is formed, as illustrated in FIG. 15D, the masked ion implantation process that forms the n-doped well 720 may be performed prior to formation of the erase-side gate structure EGS or prior to formation of the dielectric gate spacer 756 of the erase-side gate structure EGS.

The n-doped well 720 comprises n-type dopants at an average atomic concentration which is herein referred to as a third n-type dopant atomic concentration. The third n-type dopant atomic concentration is greater than the average atomic concentration of n-type dopants within the first lightly n-doped extension region 726 (which is the first n-type dopant atomic concentration) and is less than the average atomic concentration of n-type dopants within the first heavily n-doped semiconductor region 74B (which is the second n-type dopant atomic concentration). In one embodiment, the third n-type dopant atomic concentration may be in a range from 2×10¹⁸/cm³ to 5×10¹⁹/cm³, although lesser and greater atomic concentrations may also be employed.

The depth of the bottom surface of the n-doped well 720 can be greater than the depth of the first lightly n-doped extension region 726, and can be less than the depth of the bottom surfaces of the shallow trench isolation structures 702. In an illustrative example, the depth of the bottom surface of the n-doped well 720 may be in a range from 120 nm to 350 nm, such as from 175 nm to 300 nm, although lesser and greater depths may also be employed.

If the n-doped well 720 is formed (as illustrated in FIGS. 15C and 15D), the sidewall and the bottom surface of the heavily p-doped semiconductor region 73E can be in contact with the n-doped well 720. Relative to embodiments of FIGS. 15A and 15B in which the n-doped well 720 is not employed, the location of the first p-n junction J1 is modified in embodiments of FIGS. 15C and 15D which include n-doped well 720, such that the first p-n junction J1 comprises an interface between the n-doped well 720 and the p-doped substrate semiconductor material portion 711. In one embodiment, a horizontally-extending portion of the interface between the n-doped well 720 and the p-doped substrate semiconductor material portion 711 is located at a greater depth from a horizontal plane including a top surface of the semiconductor substrate 709 than a horizontally-extending portion of an interface between the first source/drain region (726, 74B) and the p-doped substrate semiconductor material portion 711.

The bit line bias diode BD includes a p-n junction comprising at least the first lightly n-doped extension region 726 and the heavily p-doped semiconductor region 73E. The p-n junction may also include the first heavily n-doped semiconductor region 74B to form a P+/N−/N+p-n junction (73E, 726, 74B). In the embodiments illustrated in FIGS. 15C and 15D, the p-n junction may also include the n-doped well 720 to form a P+/N/N−/N+p-n junction (73E, 720, 726, 74B),

Subsequently, dielectric material layers (764, 766) can be deposited over the sense amplifier connection transistor T_S, the bit line bias diode BD, and the optional erase-side gate structure EGS, and metal interconnect structures (776, 786) can be formed within the dielectric material layers (764, 766). The dielectric material layers (764, 766) may comprise, for example, a contact-level dielectric layer 764 and a line-level dielectric layer 766. Each of the dielectric material layers (764, 766) may comprise any interlayer dielectric (ILD) material known in the art, such as undoped silicate glass (i.e., silicon oxide), a doped silicate glass, an organosilicate glass, etc. Optionally, the dielectric material layers (764, 766) may comprise at least one dielectric liner (not illustrated) that is deposited prior to deposition of the contact-level dielectric layer 764. Each of the dielectric material layers (764, 766) may have a respective uniform material composition throughout.

If the erase-side gate structure EGS is omitted, the entirety of a top surface segment of the first lightly n-doped extension region 726 between the first heavily n-doped semiconductor region 74B and the heavily p-doped semiconductor region 73E is in contact with a bottom surface segment of an overlying dielectric material layer (such as a contact-level dielectric layer 764) having a uniform material composition throughout. If the erase-side gate structure EGS is present, a top surface segment of the first lightly n-doped extension region 726 between the first heavily n-doped semiconductor region 74B and the heavily p-doped semiconductor region 73E is in contact with a bottom surface of the erase gate dielectric 750E and with a bottom surface of a dielectric gate spacer 756 within the erase-side gate structure EGS.

The metal interconnect structures (776, 786) comprise contact via structures 776 that vertically extend through the contact-level dielectric layer 764 and metal line structures 786 that are embedded in the line-level dielectric layer 766. The contact via structures 776 comprise an erase-node contact via structure 776E contacting the heavily p-doped semiconductor region 73E, a bit-line-node contact via structure 776B contacting the first heavily n-doped semiconductor region 74B, a sense-amplifier-node contact via structure 776S that contacts the second heavily n-doped semiconductor region 74S, and a sense-side gate contact via structure 776G that contacts the sense amplifier transistor gate electrode 755S. If the erase-side gate structure EGS is employed, the contact via structures 776 further comprise an erase-side gate contact via structure 776D that contacts the erase gate electrode 755E.

A top surface of the heavily p-doped semiconductor region 73E is in contact with the erase-node contact via structure 776E and/or a first surface segment of the bottom surface of the overlying dielectric material layer (such as a contact-level dielectric layer 764). A top surface of the first heavily n-doped semiconductor region 74B is in contact with the bit-line-node contact via structure 776B and a second surface segment of the bottom surface of the overlying dielectric material layer (such as a contact-level dielectric layer 764).

In embodiments in which the erase-side gate structure EGS is omitted, the entirety of the top surface of the heavily p-doped semiconductor region 73E is in contact with the erase-node contact via structure 776E or a first surface segment of the bottom surface of the overlying dielectric material layer (such as a contact-level dielectric layer 764); and the entirety of the top surface of the first heavily n-doped semiconductor region 74B is in contact with the bit-line-node contact via structure 776B or a second surface segment of the bottom surface of the overlying dielectric material layer (such as a contact-level dielectric layer 764).

In embodiments in which the erase-side gate structure EGS is present, the entirety of the top surface of the heavily p-doped semiconductor region 73E is in contact with the erase-node contact via structure 776E or a first surface segment of the bottom surface of the overlying dielectric material layer (such as a contact-level dielectric layer 764) or a first bottom surface segment of a dielectric gate spacer of the erase-side gate structure EGS; and the entirety of the top surface of the first heavily n-doped semiconductor region 74B is in contact with the bit-line-node contact via structure 776B or a second surface segment of the bottom surface of the overlying dielectric material layer (such as a contact-level dielectric layer 764) or a second bottom surface segment of a dielectric gate spacer of the erase-side gate structure EGS.

In embodiments in which an erase-side gate structure EGS is present, the erase-side gate structure EGS is in contact with a top surface segment of the first lightly n-doped extension region 726 between the first heavily n-doped semiconductor region 74B and the heavily p-doped semiconductor region 73E. The erase-side gate structure EGS comprises an erase gate dielectric 750E and an erase gate electrode 755E. The erase gate electrode 755E is electrically connected to the heavily p-doped semiconductor region 73E through one of the metal line structures 786. For example, the metal line structures 786 may comprise an erase-node metal line structure 786E electrically connecting the erase-node contact via structure 776E and the erase-side gate contact via structure 776D.

Generally, the metal line structures 786 comprise the erase-node metal line structure 786E that contacts the erase-node contact via structure 776E, a bit-line-node metal line structure 786B that contacts the bit-line-node contact via structure 776B, a sense-amplifier-node metal line structure 786S that contacts the sense-amplifier-node contact via structure 776S, and a sense-side gate metal line structure 786G that contacts the sense-side gate contact via structure 776G.

If the erase-side gate structure EGS is present, the erase-node contact via structure 776E contacts the heavily p-doped semiconductor region 73E; the erase-side gate contact via structure 776D contacts the erase gate electrode 755E; and the erase-node metal line structure 786E contacts the erase-node contact via structure 776E and the erase-side gate contact via structure 776D.

In one embodiment, an overlying dielectric material layer (such as a contact-level dielectric layer 764) in contact with a top surface of the first source/drain region (726, 74B), a top surface of a second source/drain region (722, 74S), and a top surface segment of the first lightly n-doped extension region 726 that is located between a gate stack of the sense amplifier connection transistor T_S and the first source/drain region (726, 74B).

In one embodiment, the p-doped well 713 can be located between the second source/drain region (722, 74S) and the p-doped substrate semiconductor material portion 711. The p-doped well 713 comprises p-type dopants at a higher average atomic concentration than the first p-type dopant atomic concentration, i.e., the average atomic concentration of p-type dopants in the p-doped substrate semiconductor material portion 711. In one embodiment, the depth of a bottom surface of the p-doped well 713 from a horizontal plane including a top surface of the semiconductor substrate 709 is greater than a depth of a bottom surface of the shallow trench isolation structure 702 from the horizontal plane. In one embodiment, the first heavily n-doped semiconductor region 74B is vertically spaced from the p-doped substrate semiconductor material portion 711 by a horizontally-extending portion of the first lightly n-doped extension region 726.

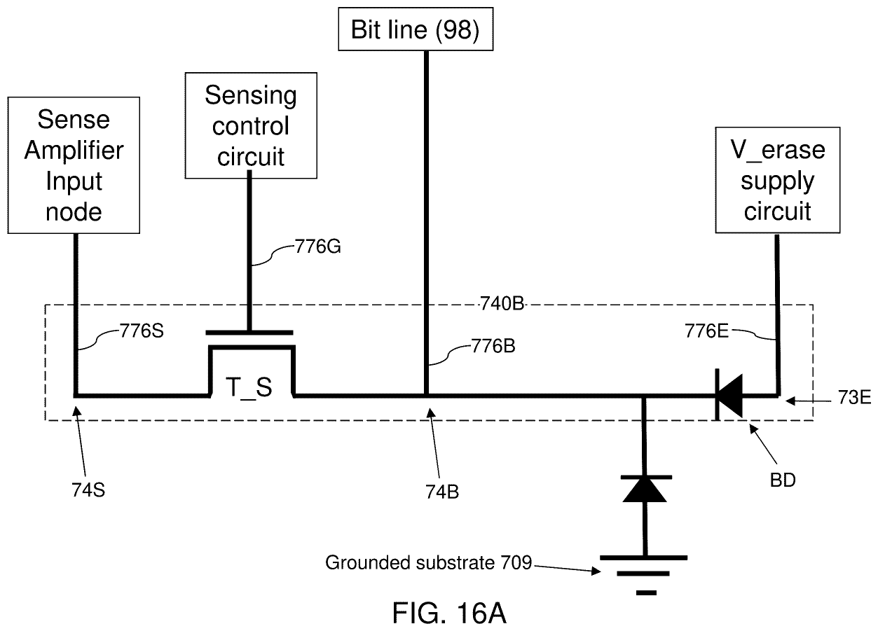

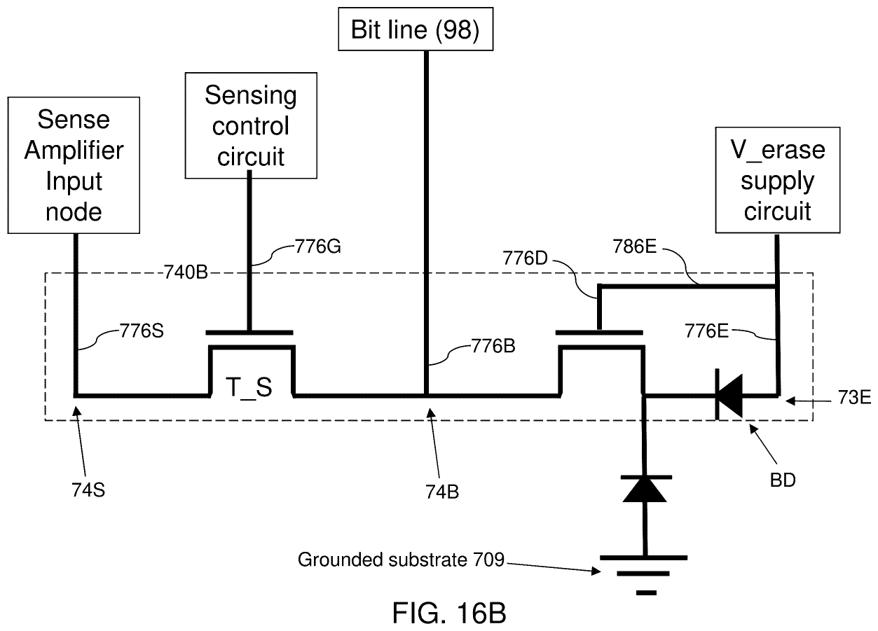

FIGS. 16A and 16B are first and second exemplary circuit schematics of the bit line drivers 740B of the present disclosure, respectively. FIG. 16A represents a circuit schematic for the embodiments illustrated in FIGS. 15A and 15C. FIG. 16B represents a circuit schematic for the embodiments illustrated in FIGS. 15B and 15D.

Referring to FIGS. 16A, 15A, and 15C, the first heavily n-doped semiconductor region 74B is electrically connected to a bit line 98, for example, through the bit-line-node contact via structure 776B and the bit-line-node metal line structure 786B. The first heavily n-doped semiconductor region 74B comprises both an active region (e.g., source or drain) of the transistor T_S and a doped region of the bit line bias diode BD. The second heavily n-doped semiconductor region 74S is electrically connected to a sense amplifier input node, for example, through the sense-amplifier-node contact via structure 776S and the sense-amplifier-node metal line structure 786S. The heavily p-doped semiconductor region 73E is electrically connected to an erase voltage supply circuit. The output of the erase voltage supply circuit is switchable between a ground voltage (to be applied while an erase operation is not performed) and an erase bias voltage (to be applied during an erase operation). The heavily p-doped semiconductor region 73E is electrically connected to the erase voltage supply circuit through the erase-node contact via structure 776E and the erase-node metal line structure 786E.

The configuration described with reference to FIGS. 16B, 15B, and 15D can be derived from the configuration described with reference to FIGS. 16A, 15A, and 15C by forming the erase-side gate structure EGS, and by electrically biasing the erase gate electrode 755E at the same bias voltage as the heavily p-doped semiconductor region 73E.

In order to apply a programming or read voltage to the bit line 98, a programming or read voltage is applied to the second heavily n-doped semiconductor region 74S using the sense-amplifier-node contact via structure 776S, and a gate voltage is applied to the sense amplifier transistor T_S gate electrode 755S using the sense-side gate contact via structure 776G. No voltage is applied to the erase-node contact via structure 776E. The gate voltage actives the transistor and causes the programming or read current to flow from second heavily n-doped semiconductor region 74S through the transistor channel 715, the first lightly n-doped extension region 726, the first heavily n-doped semiconductor region 74B, the bit-line-node contact via structure 776B and the bit-line-node metal line structure 786B to the bit line 98. However, the current does not flow into the erase-node contact via structure 776E because it is cut off by the bit line bias diode DD which is reverse biased. The programming voltage may be a positive voltage. The read voltage may be a positive voltage that is smaller than the programming voltage. The gate voltage may be a positive voltage that is greater than the programming voltage.

In order to apply an erase voltage to the bit line 98, an erase voltage is applied to the heavily p-doped semiconductor region 73E using the erase-node contact via structure 776E. A low inhibit voltage (which is lower than the programming or read voltage) may optionally be applied to the second heavily n-doped semiconductor region 74S using the sense-amplifier-node contact via structure 776S, and no gate voltage is applied to the sense amplifier transistor T_S gate electrode 755S using the sense-side gate contact via structure 776G. The sense amplifier transistor T_S remains inactive, and an erase current flows through the bit line bias diode DD from the erase-node contact via structure 776E through the heavily p-doped semiconductor region 73E, the first lightly n-doped extension region 726, the first heavily n-doped semiconductor region 74B, the bit-line-node contact via structure 776B and the bit-line-node metal line structure 786B to the bit line 98. The bit line bias diode is forward bias during the application of the erase voltage, and permits the erase current to flow to the bit line 98.

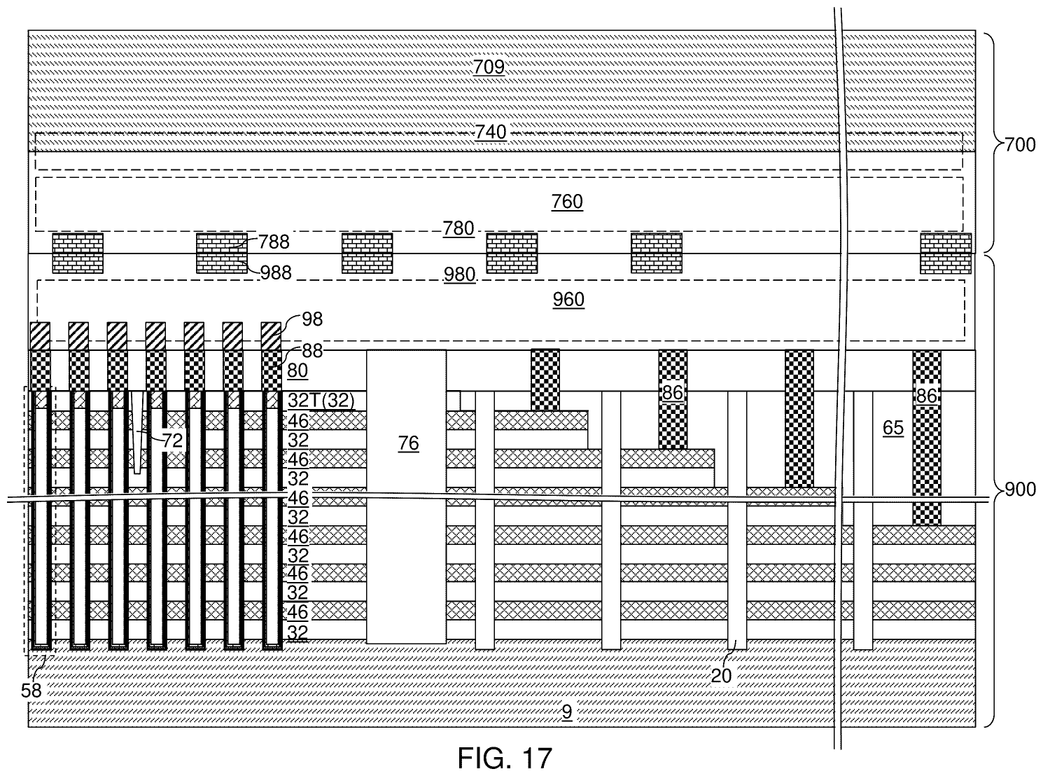

Referring to FIG. 17, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900. Upon bonding the logic die 700 to the memory die 900, the first heavily n-doped semiconductor regions 74B in the bit line driver 740B are electrically connected to the bit lines 98 in the memory die 900.

Thus, a semiconductor structure (700, 900) includes a three-dimensional memory array including a three-dimensional array of memory elements 54, word lines 46, and bit lines 98, and a bit line driver 740B including an array of unit bit-line-bias structures UBLBS. Each of the unit bit-line-bias structures includes a sense amplifier connection transistor T_S and a bit line bias diode DD that are both electrically connected to a respective one of the bit lines 98.

In one embodiment, the sense amplifier connection transistor and the bit line bias diode are both electrically connected to the respective one of the bit lines 98 through a common doped region 74B.

In one embodiment the three-dimensional memory array is located in a memory die 900; the bit line driver 740B is located in a logic die 700 that is bonded to the memory die 900; a first n-type doped active region 74S of the sense amplifier connection transistor is electrically connected to a sense amplifier circuit; a p-type doped region 73E of the bit line bias diode is electrically connected to an erase voltage supply circuit; and the common doped region 74B comprises a second n-type doped active region of the sense amplifier connection transistor is electrically connected to the respective one of the bit lines 98.

The semiconductor structure illustrated in FIG. 17 can be formed by forming a three-dimensional memory array including a three-dimensional array of memory elements, word lines (comprising a portion of electrically conductive layers 46), and bit lines 98; forming a bit line driver 740B comprising an array of unit bit-line-bias structures UBLBS; and electrically connecting the first heavily n-doped semiconductor regions 74B to a respective one of the bit lines 98. Each of the unit bit-line-bias structures UBLBS comprises: a p-doped substrate semiconductor material portion 711 located in a semiconductor substrate 709, including p-type dopants at a first p-type-dopant atomic concentration, and laterally surrounded by a shallow trench isolation structure 702, a sense amplifier connection transistor T_S comprising a channel region 715 that comprises a surface region of the p-doped substrate semiconductor material portion 711, a first source/drain region (726, 74B) that comprises a first lightly n-doped extension region 726 and a first heavily n-doped semiconductor region 74B which is embedded within the first lightly n-doped extension region 726, and a second source/drain region (722, 74S) that comprises a second heavily n-doped semiconductor region 74S which is electrically connected to an input node of a sense amplifier, wherein a first p-n junction J1 is present between the first source/drain region (726, 74B) and the p-doped substrate semiconductor material portion 711, and a heavily p-doped semiconductor region 73E in contact with a sidewall of the shallow trench isolation structure 702, electrically connected to an output node of an erase bias voltage supply circuit, and laterally spaced from the first heavily n-doped semiconductor region 74B at least by a portion of the first lightly n-doped extension region 726, wherein a second p-n junction J2 is present at a sidewall and a bottom surface of the heavily p-doped semiconductor region 73E.

In one embodiment, the three-dimensional memory array is formed in a memory die 900; the bit line driver 740B is formed in a logic die 700; and the method comprises bonding the logic die 700 to the memory die 900, such that the first heavily n-doped semiconductor regions 74B are electrically connected to the respective one of the bit lines 98. In one embodiment, an n-doped well 720 may be formed between the first lightly n-doped extension region 726 and the heavily p-doped semiconductor region 73E. The n-doped well 720 comprises n-type dopants at an average atomic concentration that is greater than an average atomic concentration of n-type dopants within the first lightly n-doped extension region 726 and is less than an average atomic concentration of n-type dopants within the first heavily n-doped semiconductor region 74B.

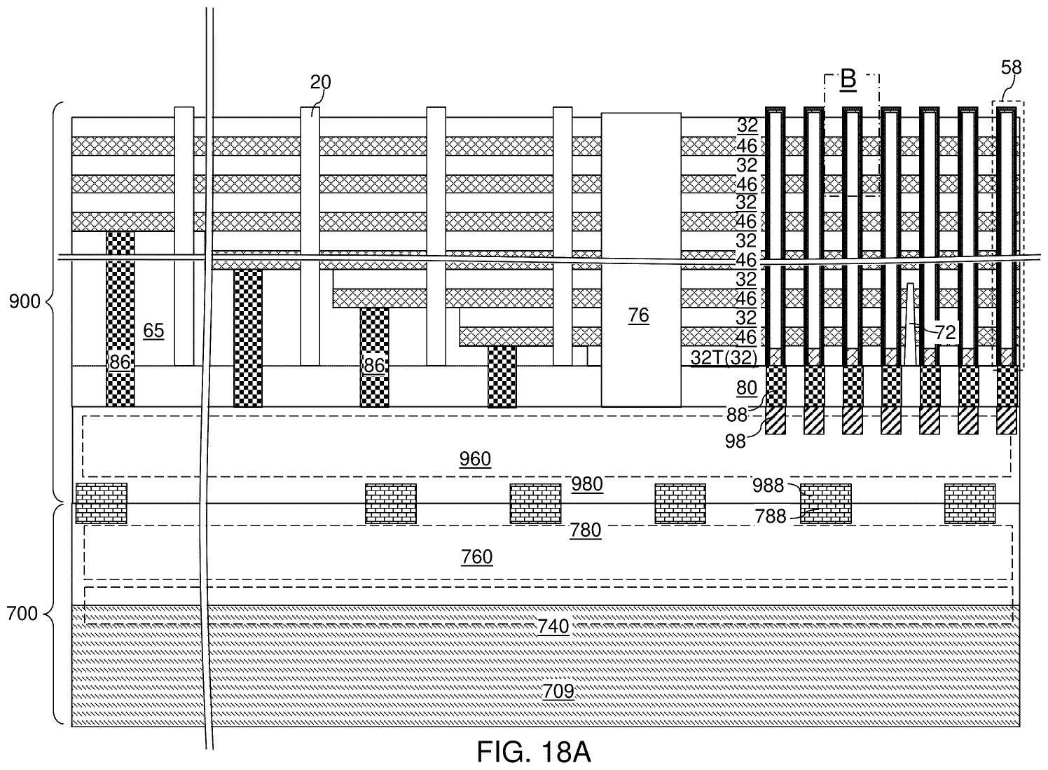

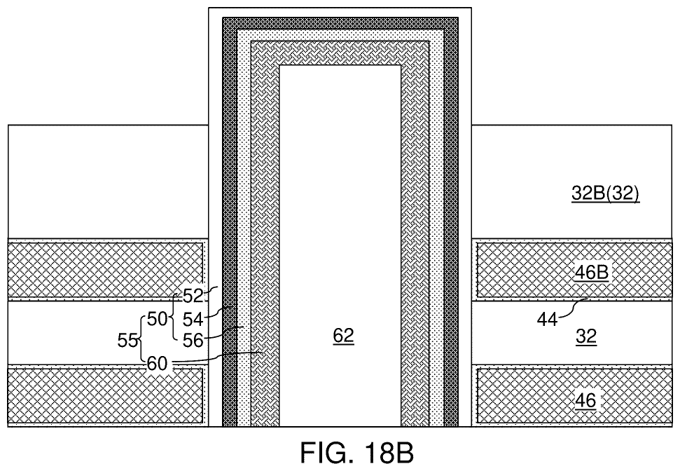

Referring to FIGS. 18A and 18B, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9. The optional outer blocking dielectric layers 44 are illustrated in FIG. 16B, each of which embeds a respective electrically conductive layer 46. Alternatively, the optional outer blocking dielectric layers 44 may be omitted.

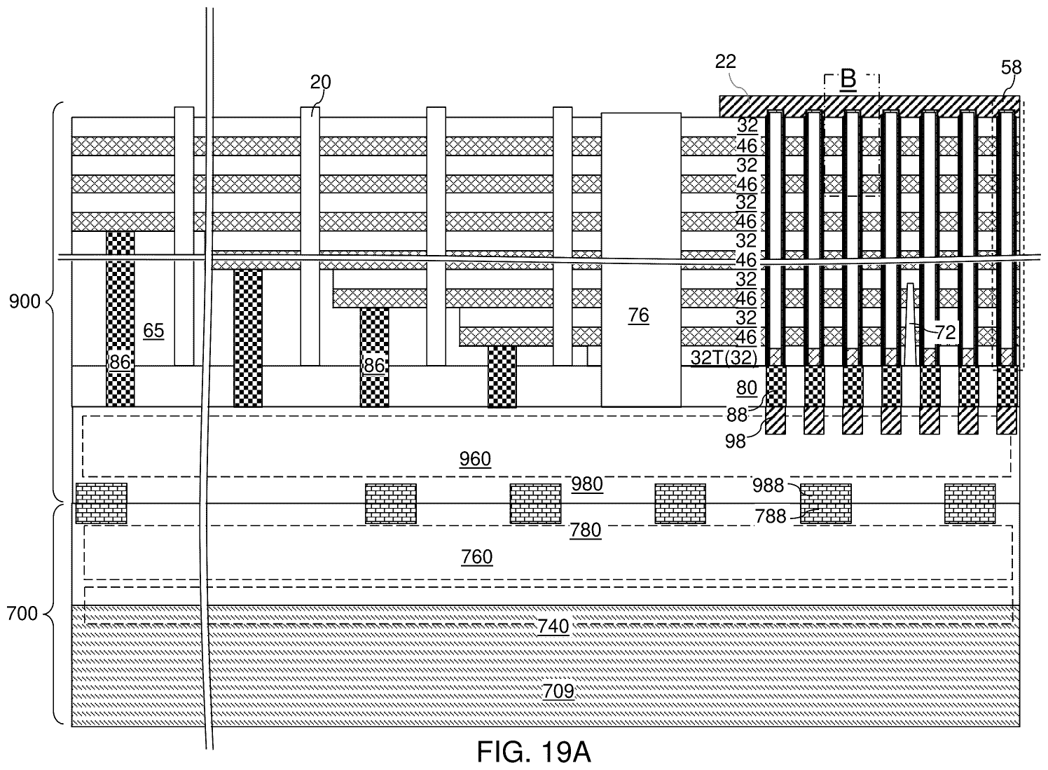

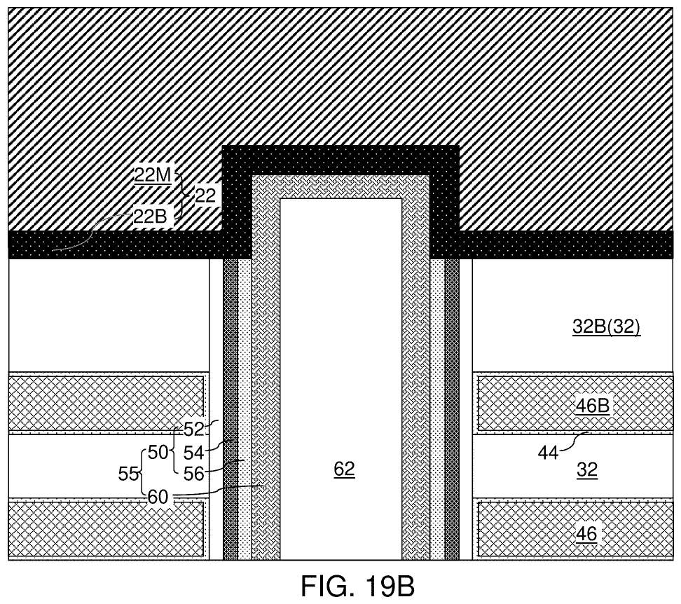

Referring to FIGS. 19A and 19B, a sequence of isotropic etch processes may be performed to remove physically exposed portions of the memory films 50. Bottom end portions of the vertical semiconductor channels 60 can be physically exposed. At least one metallic material can be deposited and patterned to form a source layer 22. In one embodiment, the source layer 22 may comprise a source metallic barrier liner 22B and a source metal layer 22M. In one embodiment, the source metallic barrier liner 22B may comprise a metallic diffusion barrier material such as TIN, TaN, WN, and/or MON, and the source metal layer 22M may comprise a high-electrical-conductivity metal such as Cu, W, Mo, Co, Ru, etc.

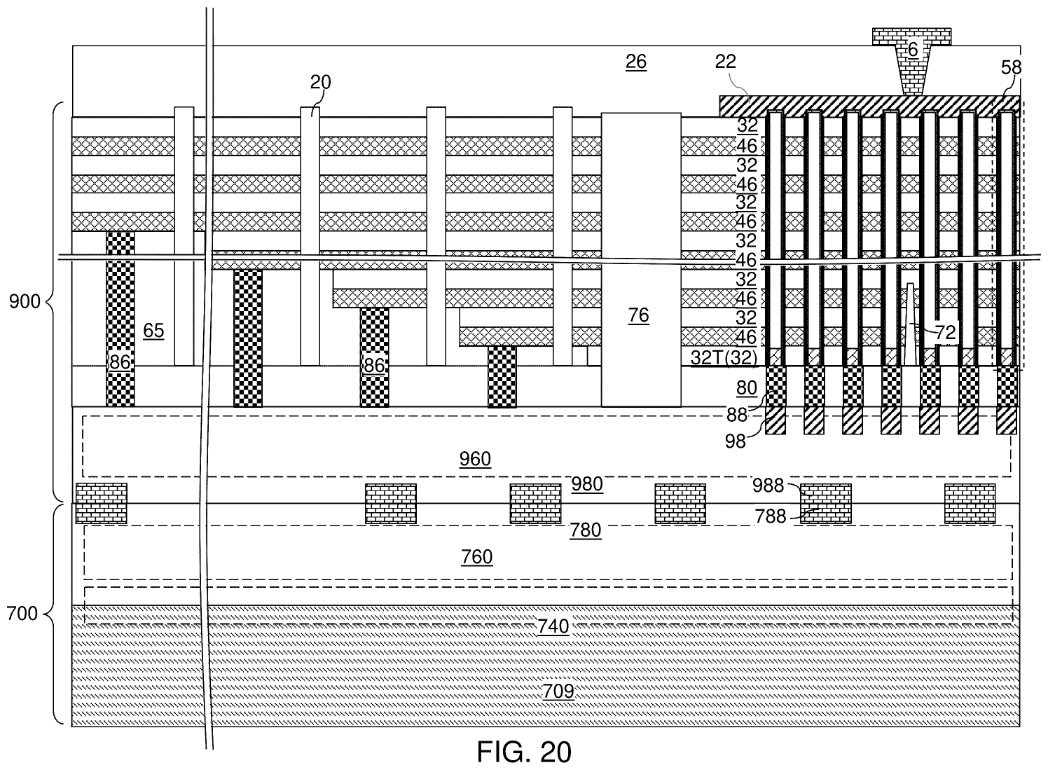

Referring to FIG. 20, a backside dielectric layer 26 can be deposited over the source layer 22. An electrically conductive source contact structure 6 can be formed through the backside dielectric layer 26 on the source layer 22.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a three-dimensional memory array including a three-dimensional array of memory elements, word lines, and bit lines; and
a bit line driver comprising an array of unit bit-line-bias structures, wherein each of the unit bit-line-bias structures comprises a sense amplifier connection transistor and a bit line bias diode that are both electrically connected to a respective one of the bit lines.

2. The semiconductor structure of claim 1, wherein the sense amplifier connection transistor and the bit line bias diode are both electrically connected to the respective one of the bit lines through a common doped region.

3. The semiconductor structure of claim 2, wherein:
the three-dimensional memory array is located in a memory die;
the bit line driver is located in a logic die that is bonded to the memory die;
a first n-type doped active region of the sense amplifier connection transistor is electrically connected to a sense amplifier circuit;
a p-type doped region of the bit line bias diode is electrically connected to an erase voltage supply circuit; and
the common doped region comprises a second n-type doped active region of the sense amplifier connection transistor is electrically connected to the respective one of the bit lines.

4. The semiconductor structure of claim 1, wherein each of the unit bit-line-bias structures comprises:
a p-doped substrate semiconductor material portion located in a semiconductor substrate, including p-type dopants at a first p-type-dopant atomic concentration, and laterally surrounded by a shallow trench isolation structure;
a sense amplifier connection transistor comprising a channel region that comprises a surface region of the p-doped substrate semiconductor material portion, a first source/drain region that comprises a first lightly n-doped extension region and a first heavily n-doped semiconductor region which is embedded within the first lightly n-doped extension region and electrically connected to a respective one of the bit lines, and a second source/drain region that comprises a second heavily n-doped semiconductor region which is electrically connected to an input node of a sense amplifier, wherein a first p-n junction is present between the first source/drain region and the p-doped substrate semiconductor material portion; and
a heavily p-doped semiconductor region electrically connected to an output node of an erase bias voltage supply circuit, and laterally spaced from the first heavily n-doped semiconductor region at least by a portion of the first lightly n-doped extension region, wherein a second p-n junction is present at a sidewall and a bottom surface of the heavily p-doped semiconductor region.

5. The semiconductor structure of claim 4, wherein the sidewall and the bottom surface of the heavily p-doped semiconductor region are in contact with the first lightly n-doped extension region.

6. The semiconductor structure of claim 5, wherein an entirety of the bottom surface of the heavily p-doped semiconductor region is in contact with the first lightly n-doped extension region.

7. The semiconductor structure of claim 5, wherein a horizontally-extending portion of the second p-n junction is vertically spaced from a horizontally-extending portion of the first p-n junction by a uniform vertical spacing.

8. The semiconductor structure of claim 5, wherein an entirety of a top surface segment of the first lightly n-doped extension region between the first heavily n-doped semiconductor region and the heavily p-doped semiconductor region is in contact with a bottom surface segment of an overlying dielectric material layer having a uniform material composition throughout.

9. The semiconductor structure of claim 4, further comprising an n-doped well located between the first lightly n-doped extension region and the heavily p-doped semiconductor region and comprising n-type dopants at an average atomic concentration that is greater than an average atomic concentration of n-type dopants within the first lightly n-doped extension region and is less than an average atomic concentration of n-type dopants within the first heavily n-doped semiconductor region.

10. The semiconductor structure of claim 9, wherein the sidewall and the bottom surface of the heavily p-doped semiconductor region are in contact with the n-doped well.

11. The semiconductor structure of claim 9, wherein:
the first p-n junction comprises an interface between the n-doped well and the p-doped substrate semiconductor material portion; and
a horizontally-extending portion of the interface between the n-doped well and the p-doped substrate semiconductor material portion is located at a greater depth from a horizontal plane including a top surface of the semiconductor substrate than a horizontally-extending portion of an interface between the first source/drain region and the p-doped substrate semiconductor material portion.

12. The semiconductor structure of claim 4, further comprising:
an erase-node contact via structure contacting the heavily p-doped semiconductor region, wherein a top surface of the heavily p-doped semiconductor region is in contact with the erase-node contact via structure and a first surface segment of the bottom surface of the overlying dielectric material layer; and
a bit-line-node contact via structure contacting the first heavily n-doped semiconductor region, wherein a top surface of the first heavily n-doped semiconductor region is in contact with the bit-line-node contact via structure and a second surface segment of the bottom surface of the overlying dielectric material layer.

13. The semiconductor structure of claim 4, further comprising an erase-side gate structure in contact with a top surface segment of the first lightly n-doped extension region between the first heavily n-doped semiconductor region and the heavily p-doped semiconductor region, wherein the erase-side gate structure comprises an erase gate dielectric and an erase gate electrode.

14. The semiconductor structure of claim 13, further comprising:
an erase-node contact via structure contacting the heavily p-doped semiconductor region;
an erase-side gate contact via structure contacting the erase gate electrode; and
an erase-node metal line structure contacting the erase-node contact via structure and the erase-side gate contact via structure.

15. The semiconductor structure of claim 4, further comprising an overlying dielectric material layer in contact with a top surface of the first source/drain region, a top surface of a second source/drain region, and a top surface segment of the first lightly n-doped extension region that is located between a gate stack of the sense amplifier connection transistor and the first source/drain region.

16. The semiconductor structure of claim 4, further comprising a p-doped well located between the second source/drain region and the p-doped substrate semiconductor material portion and comprising p-type dopants at a higher average atomic concentration than the first p-type-dopant atomic concentration, wherein a depth of a bottom surface of the p-doped well from a horizontal plane including a top surface of the semiconductor substrate is greater than a depth of a bottom surface of the shallow trench isolation structure from the horizontal plane.

17. A method of programming at least one of the memory elements of the semiconductor structure of claim 3, comprising:
applying a programming voltage to the first n-type doped active region of the sense amplifier connection transistor from the sense amplifier circuit; and
applying a gate voltage to a gate electrode of the sense amplifier connection transistor, such that a programming current flows through the sense amplifier transistor and the common doped region into the respective one of the bit lines while the bit line bias diode is reverse biased to block the programming current flow there through.

18. A method of reading at least one of the memory elements of the semiconductor structure of claim 3, comprising:
applying a read voltage to the first n-type doped active region of the sense amplifier connection transistor from the sense amplifier circuit; and
applying a gate voltage to a gate electrode of the sense amplifier connection transistor, such that a read current flows through the sense amplifier transistor and the common doped region into the respective one of the bit lines, while the bit line bias diode is reverse biased to block the read current flow there through.

19. A method of erasing at least one of the memory elements of the semiconductor structure of claim 3, comprising:
applying an erase voltage to the p-type doped region of the bit line bias diode from the erase voltage supply circuit to forward bias the bit line bias diode such that a read current flows through the bit line bias diode and the common doped region into the respective one of the bit lines; and
not applying a gate voltage to a gate electrode of the sense amplifier connection transistor, such that sense amplifier connection transistor remains inactive to block the read current flow there through.

20. A method of forming a semiconductor structure, comprising:
forming a three-dimensional memory array including a three-dimensional array of memory elements, word lines, and bit lines;
forming a bit line driver comprising an array of unit bit-line-bias structures, wherein each of the unit bit-line-bias structures comprises a sense amplifier connection transistor and a bit line bias diode; and
bonding the three-dimensional memory array to the bit line driver, such that both the sense amplifier connection transistor and the bit line bias diode are electrically connected to a respective one of the bit lines.
